(19) United States
(12) Patent Application Publication
(10) Pub. No.: US 2026/0090374 A1
(43) Pub. Date: Mar. 26, 2026

(54) SEMICONDUCTOR PACKAGE AND METHODS OF MANUFACTURING THE SAME

(71) Applicant: Taiwan Semiconductor Manufacturing Company, Ltd., Hsinchu (TW)

(72) Inventors: Hsien-Pin Hu, Hsinchu County (TW); Tsung-Yu Chen, Hsinchu City (TW); Ying-Ching Shih, Hsinchu City (TW); Jung-Wei Cheng, Hsinchu City (TW)

(73) Assignee: Taiwan Semiconductor Manufacturing Company, Ltd., Hsinchu (TW)

(21) Appl. No.: 18/898,617

(22) Filed: Sep. 26, 2024

(51) Int. Cl. H01L 23/367; H01L 23/373; H01L 25/065; H01L 25/18

(52) U.S. Cl. CPC H10W 40/22; H10W 40/25; H10W 90/00; H10W 90/288

(57) ABSTRACT

A semiconductor package includes a substrate, a package, a plurality of semiconductor devices, and a thermal dissipating module. The package is disposed over and electrically coupled to the substrate, and includes a plurality of dies. The semiconductor devices are disposed over and electrically coupled to the substrate and laterally next to the package. The thermal dissipating module is disposed over the substrate and includes a first thermal dissipating element connected to and thermally coupled to the package through a first thermal interface material and a second thermal dissipating element connected to and thermally coupled to the semiconductor devices through a second thermal interface material, where a thermal conductivity of the first thermal interface material is different from a thermal conductivity of the second thermal interface material.

### BACKGROUND

Developments in shrinking sizes of semiconductor devices and electronic components make the integration of more devices and components into a given volume possible and lead to high integration density of various semiconductor devices and/or electronic components. Integrated circuit applications currently have increasingly more functions built therein, and are thus formed to be increasingly larger.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIG. 8 are schematic cross-sectional views or plane views of various stages in manufacturing a semiconductor package in accordance with some embodiments of the disclosure.

FIG. 9 through FIG. 11 are schematic cross-sectional views or plane views of a semiconductor package in accordance with some alternative embodiments of the disclosure.

FIG. 12 through FIG. 14 are schematic cross-sectional views or plane views of a semiconductor package in accordance with some alternative embodiments of the disclosure.

FIG. 15 through FIG. 17 are schematic cross-sectional views or three-dimensional views of a frame structure of a thermal dissipating element in accordance with some embodiments of the disclosure.

FIG. 18 through FIG. 22 are schematic cross-sectional views or plane views of various stages in manufacturing a semiconductor package in accordance with some embodiments of the disclosure.

FIG. 23 through FIG. 27 are schematic cross-sectional views or plane views of a semiconductor package in accordance with some alternative embodiments of the disclosure.

FIG. 28 through FIG. 32 are schematic cross-sectional views or plane views of a semiconductor package in accordance with some alternative embodiments of the disclosure.

FIG. 33 through FIG. 35 are schematic cross-sectional views or three-dimensional views of a frame structure of a thermal dissipating element in accordance with some embodiments of the disclosure.

FIG. 36 is a schematic cross-sectional view of an application of a semiconductor package in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, “fifth”, “sixth”, “seventh”, and the like, may be used herein for ease of description to describe similar or different element(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the disclosure provides applicable concepts that can be embodied in a wide variety of specific contexts. The embodiments are intended to provide further explanations but are not used to limit the scope of the disclosure. The specific embodiment(s) described herein is related to a semiconductor package including a package having a semiconductor die (or chip), optical dies (or chips) arranged next to the package, and a heat dissipating module disposed over and thermally coupled to the package and the optical dies with different thermal interface materials. With such two thermal interface materials, the thermal solution of the semiconductor package is optimized. In some embodiments of the disclosure, the thermal dissipating module includes a first element disposed over and thermally coupled to the optical dies and a second element disposed over and thermally coupled to the package, where the first element is in a form of a frame (or ring) structure that has a plurality of inner bars, a plurality of outer bars and a plurality of supporting blocks connecting to the inner bars and the outer bars, so that the inner bars are arranged to surround the package and overlapped with the optical dies, the outer bars are arranged to surround the inner bars, and the supporting blocks connects the inner bars to from an inner frame or ring and connects the outer bars to form a second frame (or ring). With such frame structure, a stress buffer to the semiconductor package is obtained. The manufacture of such semiconductor package is compatible to the current and/or advanced manufacturing processes.

In some embodiments, the manufacturing method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

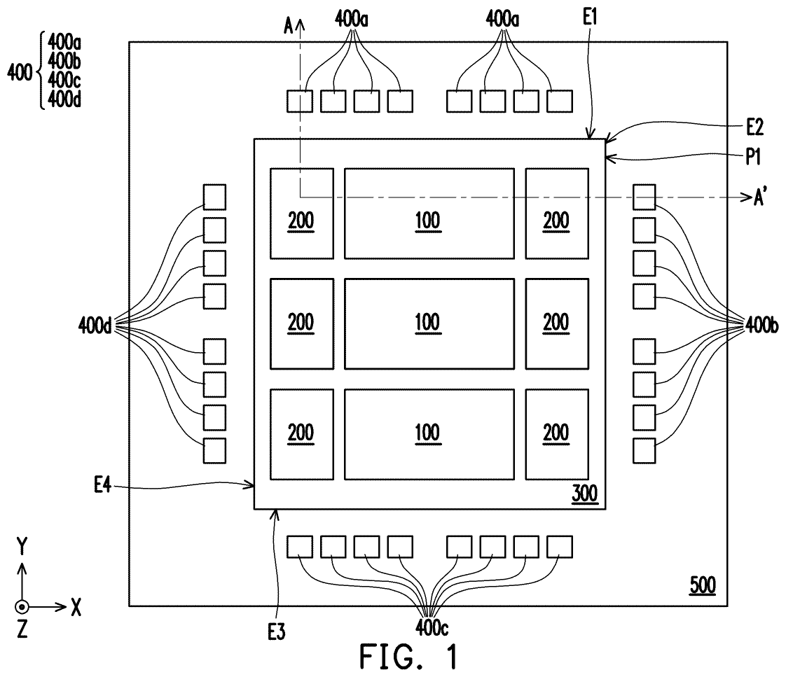

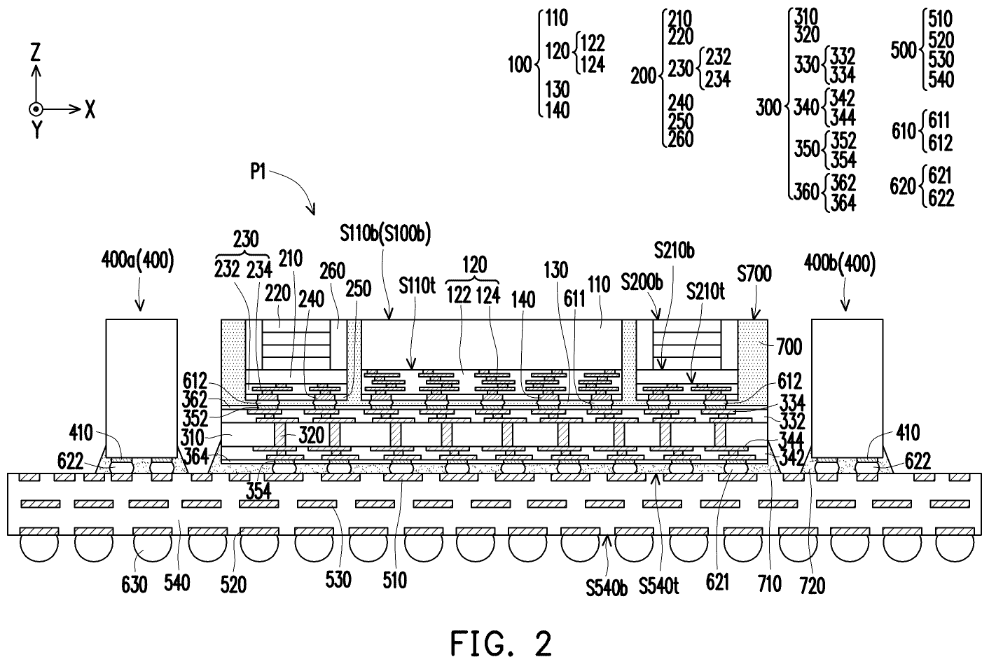

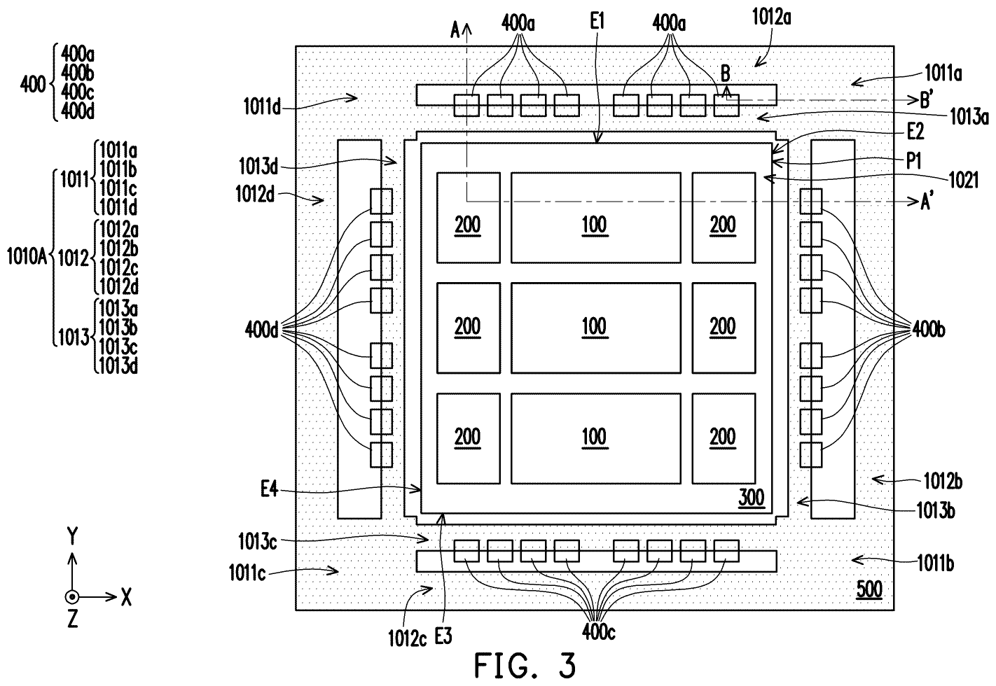

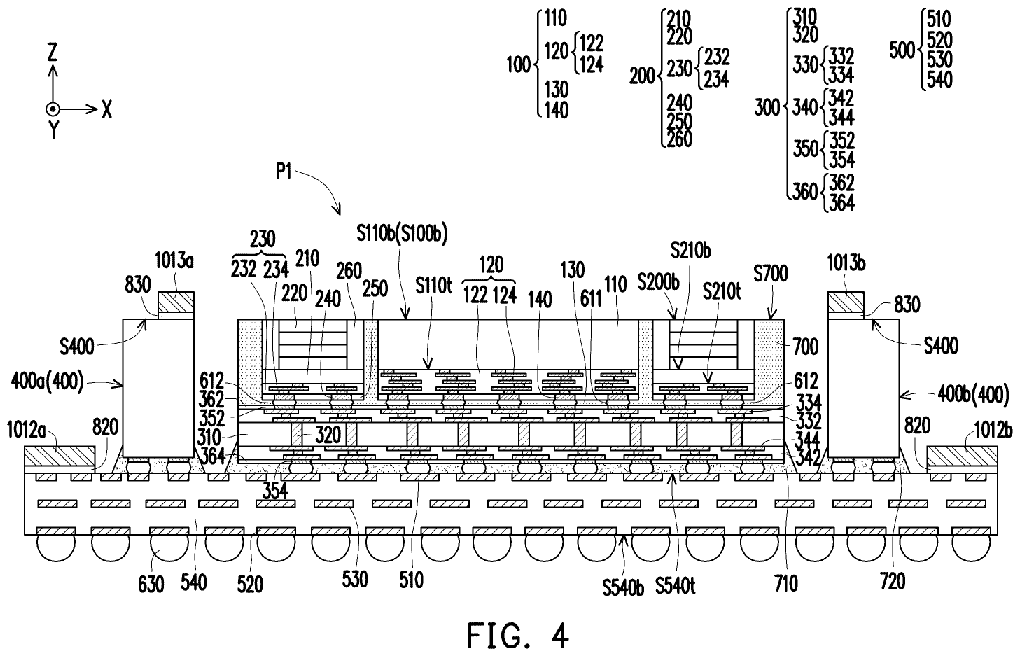

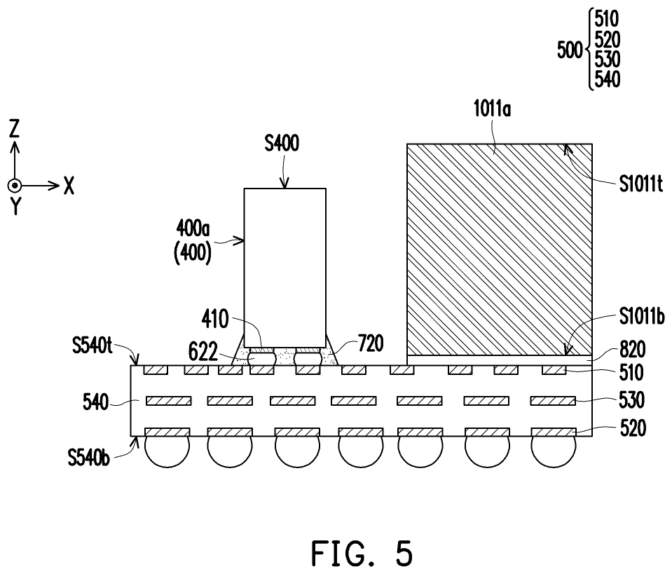

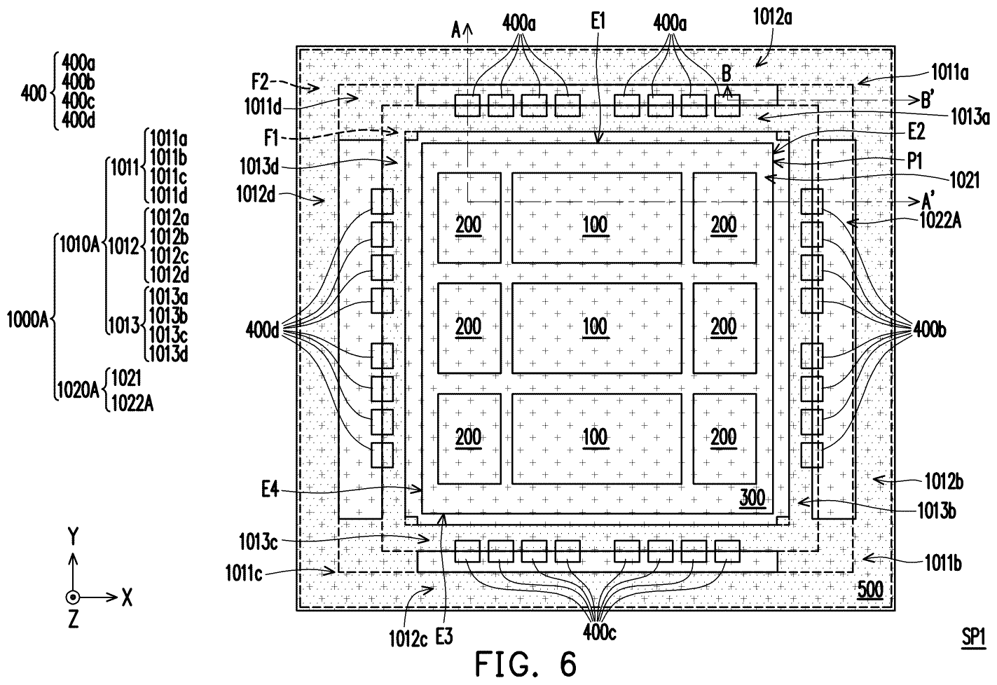

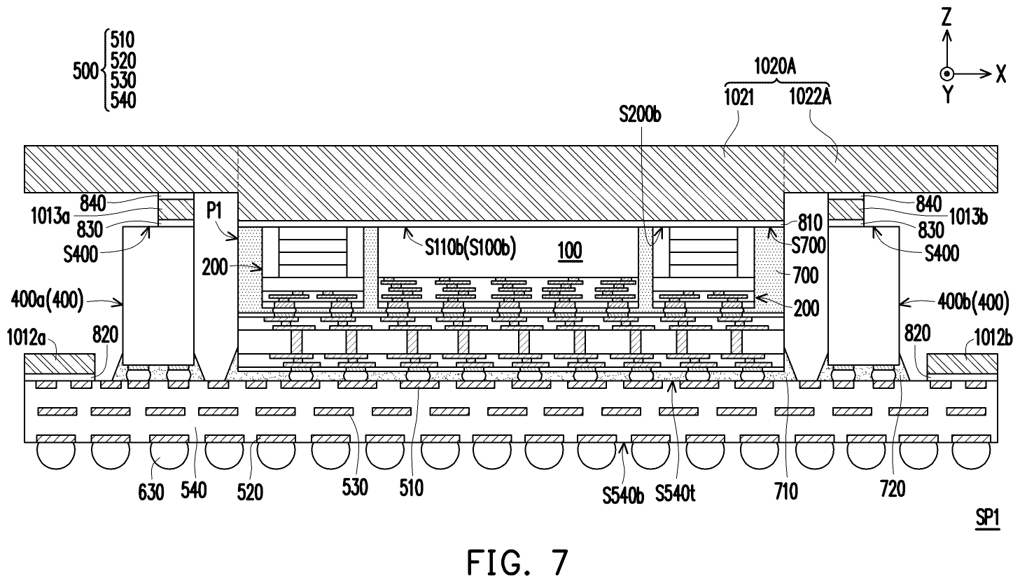

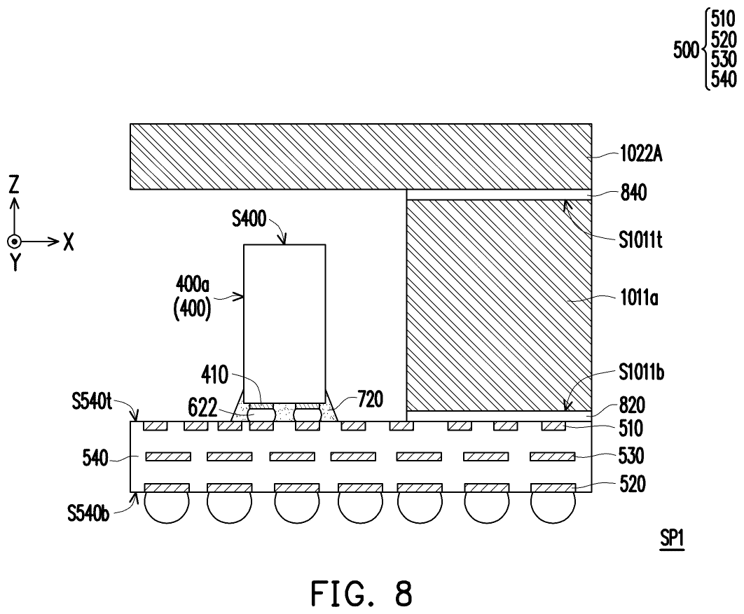

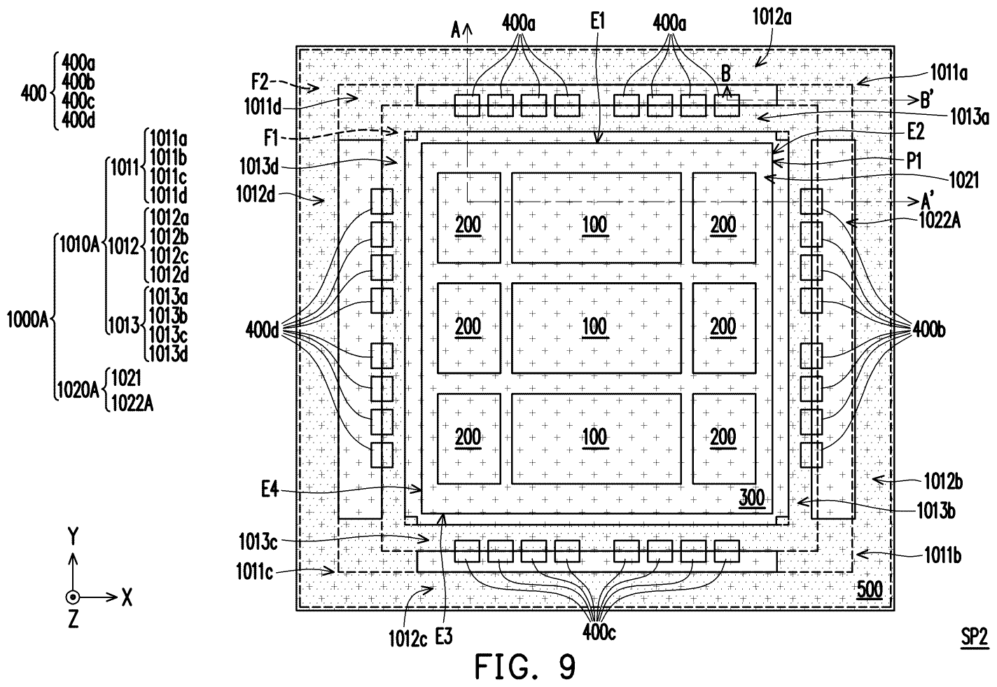

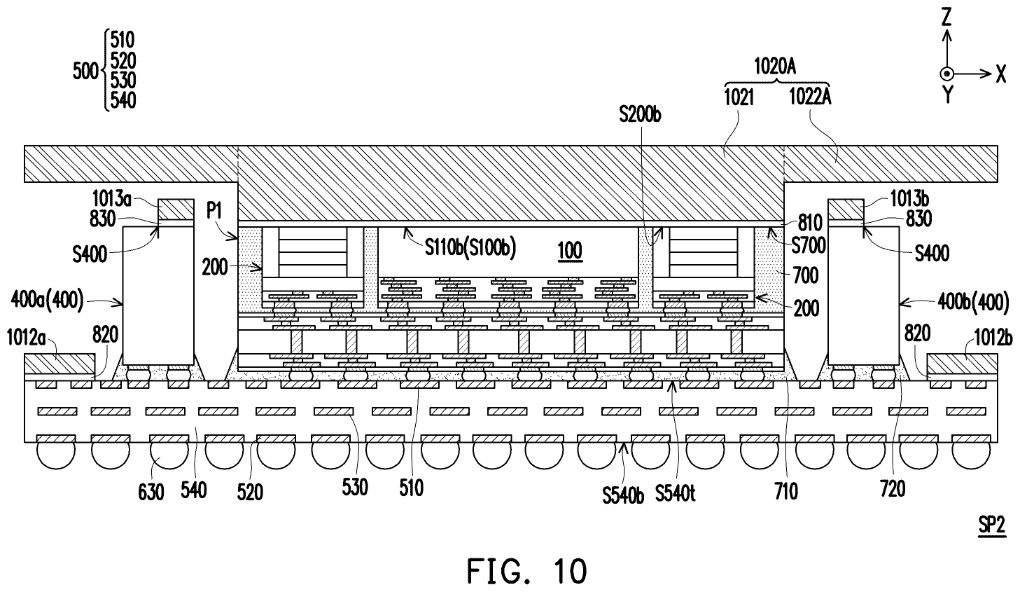

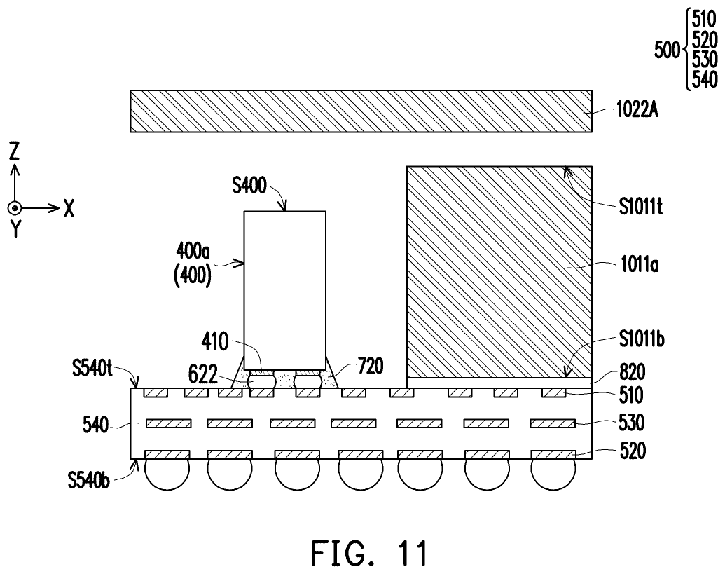

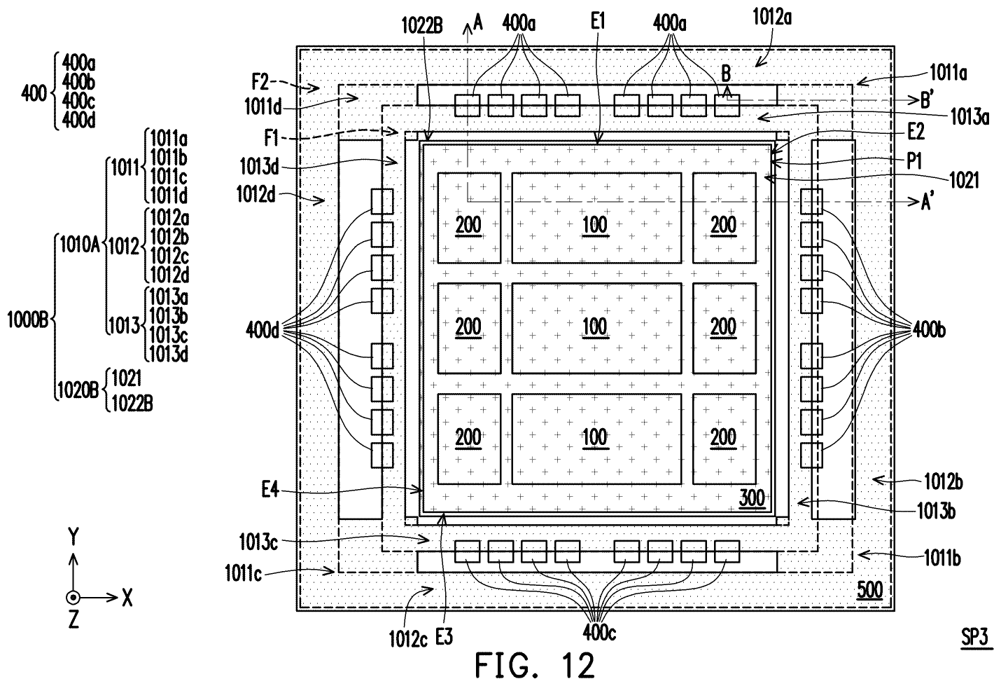

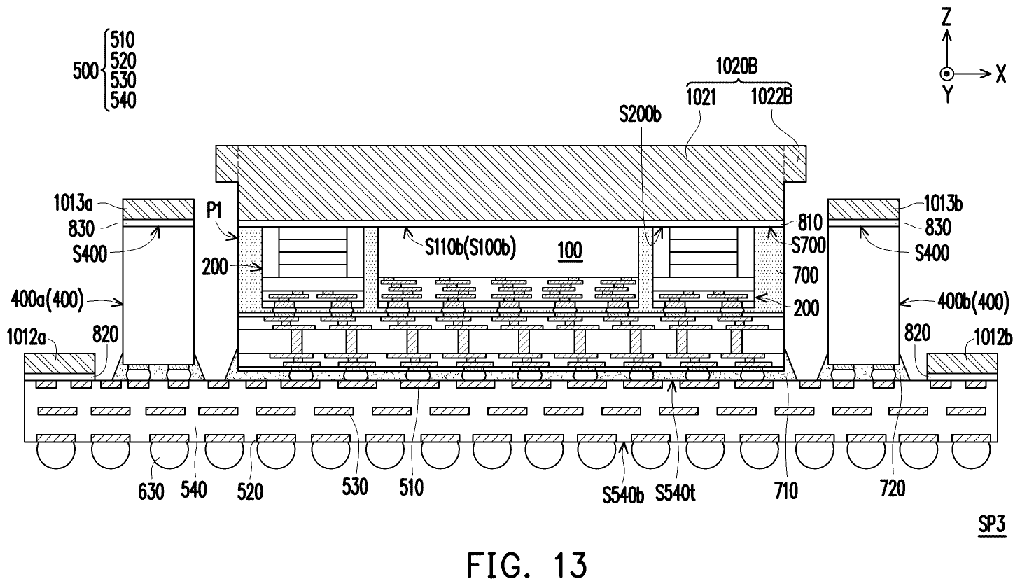

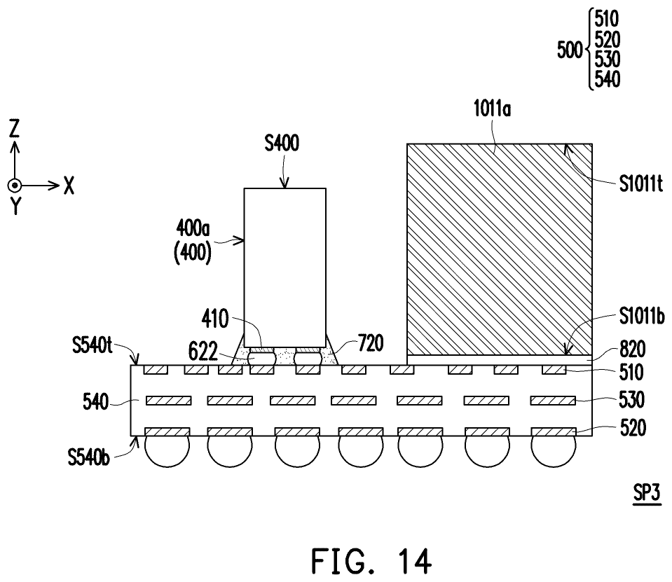

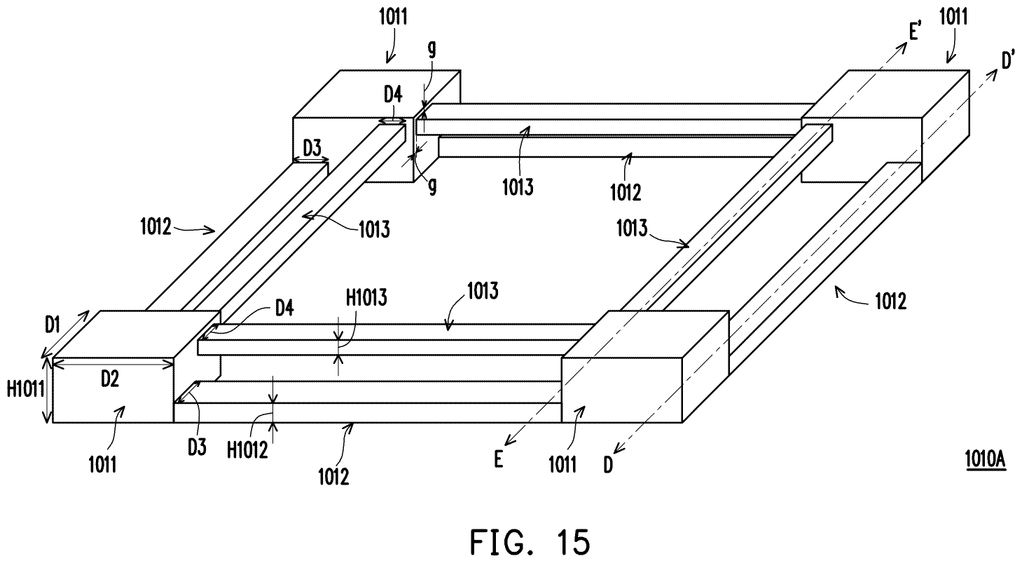

FIG. 1 through FIG. 8 are schematic cross-sectional views or plane views of various stages in manufacturing a semiconductor package (e.g., SP1) in accordance with some embodiments of the disclosure, where the cross-sectional view of FIG. 2 is taken along a line AA′ depicted in the plane view of FIG. 1, the cross-sectional views of FIG. 4 is taken along the line AA′ depicted in the plane view of FIG. 3, the cross-sectional views of FIG. 5 is taken along a line BB′ depicted in the plane view of FIG. 3, the cross-sectional views of FIG. 7 is taken along the line AA′ depicted in the plane view of FIG. 6, and the cross-sectional views of FIG. 8 is taken along the line BB′ depicted in the plane view of FIG. 6. FIG. 9 through FIG. 11 are schematic cross-sectional views or plane views of a semiconductor package (e.g., SP2) in accordance with some alternative embodiments of the disclosure, where the cross-sectional views of FIG. 10 is taken along the line AA′ depicted in the plane view of FIG. 9, and the cross-sectional views of FIG. 11 is taken along the line BB′ depicted in the plane view of FIG. 9. FIG. 12 through FIG. 14 are schematic cross-sectional views or plane views of a semiconductor package (e.g., SP3) in accordance with some alternative embodiments of the disclosure, where the cross-sectional views of FIG. 13 is taken along the line AA′ depicted in the plane view of FIG. 12, and the cross-sectional views of FIG. 14 is taken along the line BB′ depicted in the plane view of FIG. 12. FIG. 15 through FIG. 17 are schematic cross-sectional views or three-dimensional views of a frame structure of a thermal dissipating element (e.g., 1010A) in a semiconductor package (e.g., SP1, SP2, or SP3) in accordance with some embodiments of the disclosure.

Referring to FIG. 1 to FIG. 2, in some embodiment, an initial structure is provided, where the initial structure includes a substrate 500, a package P1 disposed over and electrically coupled to the substrate 500, and a plurality of semiconductor devices 400 disposed over and electrically coupled to the substrate 500. For example, the package P1 is surrounded by the semiconductor devices 400, and the package P1 is electrically coupled and electrically communicated with the semiconductor devices 400 through the substrate 500 by connectors (e.g., 620).

In some embodiments, the package P1 includes a plurality of semiconductor dies 100, a plurality of semiconductor dies 200, an interposer 300, and an insulating encapsulation 700. The semiconductor dies 100 and the semiconductor dies 200 may be disposed at a side of the interposer 300 and be further encapsulated in the insulating encapsulation 700, as shown in FIG. 2. In some embodiments, the semiconductor dies 100 are disposed on and electrically coupled to the interposer 300 through connectors 611, and the semiconductor dies 200 are disposed on and electrically coupled to the interposer 300 through connectors 612, for example. For example, the package P1 further includes the connector 611 and 612. In some embodiments, the semiconductor dies 200 are disposed at two opposite sides of the semiconductor dies 100, and the semiconductor dies 200 are electrically communicated with the semiconductor dies 100 by the interposer 300, the connectors 611 and the connectors 612. Only three semiconductor dies 100 and six semiconductor dies 200 are shown in FIG. 1 and only one semiconductor die 100 and two semiconductor dies 200 are shown in FIG. 2 for illustrative purposes, however the disclosure is not limited thereto. The number of the semiconductor die 100 and the number of semiconductor die 200 may be one, two, or more, which can be selected and/or designated depending on the demand and the design layout. Similarly, the number of the connectors 611 and the number of the connectors 612 are not limited to the drawings of the disclosure, and can be selected and/or designated depending on the demand and the design layout.

For example, as shown in FIG. 2, the semiconductor die 100 includes a semiconductor substrate 110 having a surface S110t (may referred to as an active or front surface) and a surface S110b (may referred to as a non-active or rear surface) opposite to the surface S110t, an interconnect structure 120 disposed over the surface S110t of the semiconductor substrate 110, a passivation layer 130 disposed over the interconnect structure 120, and a plurality of conductive vias 140 penetrating through the passivation 130 and electrically coupled to the interconnect structure 120, where the conductive vias 140 are laterally covered by the passivation layer 130. As shown in FIG. 2, the interconnect structure 120 is sandwiched between the semiconductor substrate 110 and the passivation layer 130 and sandwiched between the semiconductor substrate 110 and the conductive vias 140, for example.

In some embodiments, the semiconductor substrate 110 is a silicon substrate including active devices (e.g., transistors and/or memories such as N-type metal-oxide semiconductor (NMOS) and/or P-type metal-oxide semiconductor (PMOS) devices, or the like) and/or passive devices (e.g., resistors, capacitors, inductors or the like) formed therein. In some embodiments, such active devices and passive devices are formed in a front-end-of-line (FEOL) process. In an alternative embodiment, the semiconductor substrate 110 is a bulk silicon substrate, such as a bulk substrate of monocrystalline silicon, a doped silicon substrate, an undoped silicon substrate, or a SOI substrate, where the dopant of the doped silicon substrate may be an N-type dopant, a P-type dopant or a combination thereof. The disclosure is not limited thereto. Alternatively, the semiconductor substrate 110 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

In some embodiments, the interconnect structure 120 includes a dielectric structure 122 (including one or more inter-dielectric layers) and one or more patterned conductive layers 124 stacked alternately. For examples, the inter-dielectric layers are silicon oxide layers, silicon nitride layers, silicon oxy-nitride layers, or dielectric layers formed by other suitable dielectric materials, and are formed by deposition or the like. For examples, the patterned conductive layers 124 are patterned copper layers or other suitable patterned metal layers, and are formed by electroplating or deposition. However, the disclosure is not limited thereto. Alternatively, the patterned conductive layers 124 may be formed by a single or dual-damascene method. The number of the inter-dielectric layers and the number of the patterned conductive layers 124 may be less than or more than what is depicted in FIG. 2, and may be selected and/or designated depending on the demand and/or design layout; the disclosure is not specifically limited thereto. In some embodiments, the interconnect structure 120 is formed in a back-end-of-line (BEOL) process. In certain embodiments, as shown in FIG. 2, the patterned conductive layers 124 are sandwiched between the inter-dielectric layers, where a surface of the outermost layer of the patterned conductive layers 124 is at least partially exposed by an outermost layer of the inter-dielectric layers of the dielectric structure 122 to connect to later formed component(s) for electrical connection (e.g. with the conductive vias 140), and a surface of an innermost layer of the patterned conductive layers 124 is at least partially exposed by an innermost layer of the inter-dielectric layers of the dielectric structure 122 and electrically connected to the active devices and/or passive devices included in the semiconductor substrate 110.

In some embodiments, as shown in FIG. 2, the passivation layer 130 is formed on the interconnect structure 120, where parts of the interconnect structure 120 is covered by and in contact with the passivation layer 130, and rest of the interconnect structure 120 is accessibly revealed by the passivation layer 130. As shown in FIG. 2, the passivation layer 130 has a substantially planar surface (e.g., an outermost surface), for example. In certain embodiments, the outermost surface of the passivation layer 130 is leveled and may have a high degree of planarity and flatness, which is beneficial for the later-formed layers/elements (e.g., the conductive vias 140). In some embodiments, the passivation layer 130 includes a polyimide (PI) layer, a polybenzoxazole (PBO) layer, a silicon dioxide based (non-organic) layer or other suitable polymer (or organic) layer, and is formed by deposition or the like. The disclosure is not limited thereto. The disclosure does not specifically limit a thickness of the passivation layer 130 as long as the passivation layer 130 can maintain its high degree of planarity and flatness. In the disclosure, the outermost surface of the passivation layer 130 may be referred to as a front (or active) side of the semiconductor die 100, and the surface S110b of the semiconductor substrate 110 may be referred to as a back (or non-active) side S100b of the semiconductor die 100.

In some embodiments, the conductive vias 140 are formed on the interconnect structure 120 and over the semiconductor substrate 110, and sidewalls of the conductive vias 140 are wrapped around by the passivation layer 130, as least partially. In some embodiments, as shown in FIG. 2, the conductive vias 140 each penetrate through the passivation layer 130 to physically contact the surface of the outermost layer of the patterned conductive layers 124 exposed by the outermost layer of the inter-dielectric layers of the dielectric structure 122. Through the interconnect structure 120, the conductive vias 140 are electrically connected to the active devices and/or passive devices included in the semiconductor substrate 110. In some embodiments, the conductive vias 140 in physical contact with the interconnect structure 120 are extended away from the outermost surface of the passivation layer 130. For simplification, only five conductive vias 140 are presented in FIG. 2 in the semiconductor die 100 for illustrative purposes, however it should be noted that more than five conductive vias 140 may be formed; the disclosure is not limited thereto.

In some embodiments, the conductive vias 140 are formed by photolithography, plating, photoresist stripping processes or any other suitable method. The plating process may include an electroplating plating, an electroless plating, or the like. For example, the conductive vias 140 is formed by, but not limited to, forming a mask pattern (not shown) covering the passivation layer 130 with opening holes (not shown) corresponding to the surface of the outermost layer of the patterned conductive layers 124 exposed by the outermost layer of the inter-dielectric layers of the dielectric structure 122, patterning the passivation layer 130 to form contact openings (not shown) therein for exposing the surface of the outermost layer of the patterned conductive layers 124 exposed by the outermost layer of the inter-dielectric layers of the dielectric structure 122, forming a metallic material to fill the opening holes formed in the mask pattern and the contact openings formed in the passivation layer 130 to form the conductive vias 140 by electroplating or deposition, and then removing the mask pattern. The passivation layer 130 may be patterned by an etching process, such a dry etching process, a wet etching process, or the combination thereof. The mask pattern may be removed by acceptable ashing process and/or photoresist stripping process, such as using an oxygen plasma or the like. In one embodiment, the material of the conductive vias 140 includes a metal material such as copper or copper alloys, or the like.

In some embodiments, in a vertical projection on the surface S110t of the semiconductor substrate 110 along the (stacking) direction Z of the semiconductor substrate 110, the interconnect structure 120 and the passivation layer 130, the conductive vias 140 may independently be in a circle-shape, an ellipse-shape, a triangle-shape, a rectangle-shape, or the like. The shape of the conductive vias 140 is not limited in the disclosure. The shape and number of the conductive vias 140 may be selected and/or designated depending on the demand and/or design layout, and may be adjusted by changing the shape and number of the contact openings formed in the passivation layer 130.

Alternatively, the conductive vias 140 may be formed by, but not limited to, forming a first mask pattern (not shown) covering the passivation layer 130 with first opening holes (not shown) corresponding to the surface of the outermost layer of the patterned conductive layers 124 exposed by the outermost layer of the inter-dielectric layers of the dielectric structure 122, patterning the passivation layer 130 to form the contact openings (not shown) therein for exposing the surface of the outermost layer of the patterned conductive layers 124 exposed by the outermost layer of the inter-dielectric layers of the dielectric structure 122, removing the first mask pattern, conformally forming a metallic seed layer over the passivation layer 130, forming a second mask pattern (not shown) covering the metallic seed layer with second opening holes (not shown) exposing the contact openings formed in the passivation layer 130, forming a metallic material to fill the second opening holes formed in the second mask pattern and the contact openings formed in the passivation layer 130 by electroplating or deposition, removing the second mask pattern, and then removing the metallic seed layer not covered by the metallic material to form the conductive vias 140.

In some embodiments, the metallic seed layer is referred to as a metal layer, which includes a single layer or a composite layer comprising a plurality of sub-layers formed of different materials. In some embodiments, the metallic seed layer includes titanium, copper, molybdenum, tungsten, titanium nitride, titanium tungsten, combinations thereof, or the like. For example, the metallic seed layer may include a titanium layer and a copper layer over the titanium layer. The metallic seed layer may be formed using, for example, sputtering, physical vapor deposition (PVD) or the like.

In some embodiments, the semiconductor die 100 further includes a seal ring (not shown) embedded in the interconnect structure 120 to surround the patterned conductive layers 124 inside the dielectric structure 122. Owing to the seal ring, the interconnect structure 120 (e.g., of the dielectric structure 122 and the patterned conductive layers 124) is protected from the physical damages and/or the moistures or hydrogen attacks for the environment.

In some embodiments, for each semiconductor die 100, a sidewall of the semiconductor substrate 110, a sidewall of the interconnect structure 120 and a sidewall of the passivation layer 130 are substantially aligned with each other in the direction Z and together constitute a sidewall of the semiconductor die 100. For example, illustrated outermost surface of the conductive vias 140 may be substantially level with and substantially coplanar to the outermost surface of the passivation layer 130, as shown in FIG. 2. Alternatively, illustrated outermost surfaces of the conductive vias 140 are protruding away from (e.g., not level with) the outermost surface of the passivation layer 130.

It is appreciated that, in some embodiments, the semiconductor dies 100 independently described herein may be referred to as a semiconductor chip or an integrated circuit (IC). In some embodiments, the semiconductor dies 100 independently is a logic chip (e.g., a central processing unit (CPU), a graphics processing unit (GPU), a neural network processing unit (NPU), a deep learning processing unit (DPU), a tensor processing unit (TPU), a system-on-a-chip (SoC), an application processor (AP), a system-on-integrated-circuit (SoIC), and a microcontroller); a power management die (e.g., a power management integrated circuit (PMIC) die); a wireless and radio frequency (RF) die; a baseband (BB) die; a sensor die (e.g., a photo/image sensor chip); a micro-electro-mechanical-system (MEMS) die; a signal processing die (e.g., a digital signal processing (DSP) die); a front-end die (e.g., an analog front-end (AFE) die); an application-specific die (e.g., an application-specific integrated circuit (ASIC)); a field-programmable gate array (FPGA); a combination thereof; any suitable logic circuits; or the like. The semiconductor dies 100 independently may be or include a digital chip, an analog chip or a mixed signal chip. The semiconductor dies 100 independently may be a chip or an IC of combination-type, such as a WiFi chip simultaneously including both of a RF chip and a digital chip.

In alternative embodiments, the semiconductor dies 100 independently is an artificial intelligence (AI) engine such as an AI accelerator; a computing system such as an AI server, a high-performance computing (HPC) system, a high-power computing device, a cloud computing system, a networking system, an edge computing system, an immersive memory computing system (ImMC), a SoIC system, etc. ; a combination thereof; or the like.

In some embodiments, the types of all of the semiconductor dies 100 are identical. In alternative embodiments, the types of some of the semiconductor dies 100 are different from each other, while the types of some of the semiconductor dies 100 are identical types. In further alternative embodiments, the types of all of the semiconductor dies 100 are different. In some embodiments, the sizes of all of the semiconductor dies 100 are the same. In alterative embodiments, the sizes of some of the semiconductor dies 100 are different from each other, while the sizes of some of the semiconductor dies 100 are the same sizes. In further alternative embodiments, the sizes of all of the semiconductor dies 100 are different. In some embodiments, the shapes of all of the semiconductor dies 100 are identical. In alternative embodiments, the shapes of some of the semiconductor dies 100 are different from each other, while the shapes of some of the semiconductor dies 100 are identical. In further alternative embodiments, the shapes of all of the semiconductor dies 100 are different. The types, sizes and shapes of each of the semiconductor dies 100 are independent from each other, and may be selected and designed based on the demand and design layout, the disclosure is not limited thereto.

For example, as shown in FIG. 2, each of the semiconductor die 200 includes a carrier die 210 having a surface S210t and a surface S210b opposing to the surface S210t, a plurality of stacking dies 220, an interconnect structure 230 (including a dielectric structure 232 and patterned conductive layers 234), a plurality of conductive vias 240, a passivation layer 250, and an encapsulant 260, where the stacking dies 220 are sequentially disposed on and electrically coupled to the carrier die 210 (e.g., at the surface S210b), and the encapsulant 260 encapsulates the stacking dies 220 and covers the carrier die 210 exposed by the stacking dies 220. In some embodiments, the interconnect structure 230 is disposed on and electrically coupled to the carrier die 210 (e.g., at the surface S210t), the conductive vias 240 are disposed on and electrically coupled to the interconnect structure 230, and the passivation layer 250 is disposed on the interconnect structure 230 and laterally covers the conductive vias 240.

It is noted that, each of the carrier die 210 and the stacking dies 220 may further include an interconnect structure (not shown), conductive pads (not shown), a passivation layer (not shown), and a post-passivation layer (not shown). The carrier die 210 described herein may be referred as a semiconductor chip or an IC. In some embodiments, the carrier die 210 includes one or more digital chips, analog chips or mixed signal chips, such as an ASIC chip, a sensor chip, a wireless and RF chip, a logic chip or a voltage regulator chip. The logic chip may be a CPU, a GPU, a SoC, a microcontroller, or the like. In some embodiments, each of the stacking dies 220 includes a memory die (e.g., a dynamic random-access memory (DRAM) die, static random-access memory (SRAM) die, a synchronous dynamic random-access memory (SDRAM), a resistive random-access memory (RRAM) die, a magnetoresistive random-access memory (MRAM) die, a NAND flash a wide I/O memory (WIO) die, a high bandwidth memory (HBM) die, the like, etc.). That is to say, the semiconductor dies 200 each includes a hybrid memory cube (HMC) module, a HBM module, or the like; in some embodiments. For example, the stacking dies 220 of each semiconductor die 200 may be HBM dies, and the carrier die 210 may be a logic die providing control functionality for these memory dies. The details, formation and material of the interconnect structure 230 (including the dielectric structure 232 and the patterned conductive layers 234), the conductive vias 240, the passivation layer 250 is similar to or substantially identical to the details, formation and material of the interconnect structure 120 (including the dielectric structure 122 and the patterned conductive layers 124), the conductive vias 140, the passivation layer 130, and thus are not repeated herein for brevity.

In some embodiments, the material of the encapsulant 260 includes a molding compound, a molding underfill, a resin (such as epoxy), or the like. In some alternative embodiments, the material of the encapsulant 260 includes nitride such as silicon nitride, oxide such as silicon oxide, phosphosilicate glass (PSG), borosilicate glass (BSG), boron-doped phosphosilicate glass (BPSG), a combination thereof, or the like. In yet alternative embodiments, the material of each of the encapsulant 260 includes an organic material (e.g., epoxy, PI, PBO, or the like), or the mixture of inorganic and organic materials (e.g., the mixture of silicon oxide and epoxy, or the like). In some embodiments, the encapsulant 260 may be formed by a molding process, such as a compression molding process. In some alternative embodiments, the encapsulant 260 may be formed through suitable fabrication techniques such as chemical vapor deposition (CVD) (e.g., high-density plasma chemical vapor deposition (HDPCVD) or plasma-enhanced chemical vapor deposition (PECVD)). As illustrated in FIG. 2, for example, a back (or non-active) surface S200b of the semiconductor die 200 includes a surface of the encapsulant 260 and a surface of outermost stacking die 220, where the surface of the encapsulant 260 and the surface of outermost stacking die 220 are substantially leveled with and substantially coplanar to each other. Alternatively or in addition to, an integrated passives (IPD) die, a voltage regulator (VR) die, a local silicon interconnect (LSI) die with or without deep trench capacitor (DTC) features, a local silicon interconnect die with multi-tier functions such as electrical and/or optical network circuit interfaces, IPD, VR, DTC, or the like may be included to substitute one or some of the semiconductor dies 200 or be further adopted. The type of the semiconductor dies 200 independently may be selected and/or designated depending on the demand and/or design layout, and thus is not specifically limited in the disclosure.

In some embodiments, the types of all of the semiconductor dies 200 are identical. In alternative embodiments, the types of some of the semiconductor dies 200 are different from each other, while the types of some of the semiconductor dies 200 are identical types. In further alternative embodiments, the types of all of the semiconductor dies 200 are different. In some embodiments, the sizes of all of the semiconductor dies 200 are the same. In alterative embodiments, the sizes of some of the semiconductor dies 200 are different from each other, while the sizes of some of the semiconductor dies 200 are the same sizes. In further alternative embodiments, the sizes of all of the semiconductor dies 200 are different. In some embodiments, the shapes of all of the semiconductor dies 200 are identical. In alternative embodiments, the shapes of some of the semiconductor dies 200 are different from each other, while the shapes of some of the semiconductor dies 200 are identical. In further alternative embodiments, the shapes of all of the semiconductor dies 200 are different. The types, sizes and shapes of each of the semiconductor dies 200 are independent from each other, and may be selected and designed based on the demand and design layout, the disclosure is not limited thereto.

For example, as shown in FIG. 2, the interposer 300 includes a substrate 310, a plurality of through vias 320, a redistribution circuit structure 330, a redistribution circuit structure 340, a plurality of bonding pads 352, 354, and dielectric layers 362, 364. In addition to or alternatively, the redistribution circuit structure 330 and/or the redistribution circuit structure 340 may be omitted. The interposer 300 may include a substrate 310, a plurality of through vias 320, a redistribution circuit structure 330, a plurality of bonding pads 352, 354, and dielectric layers 362, 364. Alternatively, the interposer 300 may include a substrate 310, a plurality of through vias 320, a redistribution circuit structure 340, a plurality of bonding pads 352, 354, and dielectric layers 362, 364. Or, the interposer 300 may include a substrate 310, a plurality of through vias 320, a plurality of bonding pads 352, 354, and dielectric layers 362, 364. In addition to or alternatively, the bonding pads 352 and the dielectric layer 362 may be omitted, the bonding pads 354 and the dielectric layer 364 may be omitted, or the bonding pads 352, 354 and the dielectric layers 362, 364 may be omitted. The interposer 300 may be referred to as an interconnect substrate, an interconnect structure, an interconnection substrate or an interconnection structure.

In some embodiments, the substrate 310 is a wafer, such as a bulk semiconductor substrate, a silicon-on-insulator (SOI) substrate, a multi-layered semiconductor substrate, or the like. The semiconductor material of the substrate 310 may be silicon, germanium; a compound semiconductor including silicon carbide, gallium arsenic, gallium phosphide, indium phosphide, indium arsenide, and/or indium antimonide; an alloy semiconductor including silicon germanium (SiGe), GaAsP, AlInAs, AlGaAs, GaInAs, GaInP, and/or GaInAsP; or combinations thereof. The alloy SiGe may be formed over a silicon substrate. The SiGe substrate may be strained. In an alternative embodiment, other substrates, such as multi-layered or gradient substrates, may also be used. The substrate 310 may be doped or undoped. The substrate 310 may include a wide variety of devices (not shown) (also referred to as semiconductor devices) formed therein. The devices may include active devices, passive devices, or a combination thereof. The devices may include integrated circuits devices. The devices may include transistors, capacitors, resistors, diodes, photodiodes, fuse devices, jumpers, inductors, or other similar devices. The functions of the devices may include memory, processors, sensors, amplifiers, power distribution, input/output circuitry, or the like. The devices each may be referred to as a semiconductor component. Alternatively, the substrate 310 may be substantially free of active devices and passive devices, and merely provide routing functions.

In some embodiments, the through vias 320 are formed in the substrate 310 and penetrating through the substrate 310. The through vias 320 may be sometimes referred to as through-substrate-vias or through-silicon-vias as the substrate 310 is a silicon substrate. The through vias 320 may be formed by forming recesses in the substrate 310 (by, for example, etching, milling, laser techniques, a combination thereof, and/or the like) and depositing a conductive material in the recesses. The conductive material may be formed by an electro-chemical plating process, CVD, atomic layer deposition (ALD), PVD, a combination thereof, and/or the like. Examples of conductive materials are copper, tungsten, aluminum, silver, gold, a combination thereof, and/or the like. An optional thin dielectric material may be formed in the recesses, such as by using an oxidation technique, to separate the substrate 310 and the through vias 320. A thin barrier layer may be conformally formed in the recesses, such as by CVD, ALD, PVD, thermal oxidation, a combination thereof, and/or the like, to separate the substrate 310 and the optional thin dielectric material. The barrier layer may comprise a nitride or an oxynitride, such as titanium nitride, titanium oxynitride, tantalum nitride, tantalum oxynitride, tungsten nitride, a combination thereof, and/or the like. Excess conductive material and barrier layer is removed from an illustrated top surface of the substrate 310 by, for example, chemical mechanical polishing (CMP) process. Thus, the through vias 320 may comprise a conductive material, a thin barrier layer between the conductive material and the substrate 310 and an optional dielectric layer between the thin barrier layer and the substrate 310. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In some embodiments, the redistribution circuit structure 330 is formed on the illustrated top surface of the substrate 310, and is electrically connected to the substrate 310. In certain embodiments, the redistribution circuit structure 330 includes a dielectric structure 332 and one or more metallization layers 334 arranged therein for providing routing functionality. For example, the dielectric structure 332 includes one or more dielectric layers, such that the dielectric layers and the metallization layer 334 are sequentially formed, and one metallization layer 334 is sandwiched between two dielectric layers. As shown in FIG. 2, portions of an illustrated top surface of a topmost layer of the metallization layers 334 may be respectively exposed by a topmost portion (e.g., a topmost dielectric layer) of the dielectric structure 332, and portions of an illustrated bottom surface of a bottommost layer of the metallization layers 334 may be respectively exposed by a bottommost portion (e.g., a bottommost dielectric layer) of the dielectric structure 332; however, the disclosure is not limited thereto. For example, the illustrated top surface (not label) of the topmost layer of the metallization layers 334 is substantially level with an illustrated top surface (not label) of the topmost dielectric layer of the dielectric structure 332. In such case, the illustrated top surface (not label) of the topmost layer of the metallization layers 334 may be substantially coplanar to the illustrated top surface (not label) of the topmost dielectric layer of the dielectric structure 332. On the other hand, for example, the illustrated bottom surface (not label) of the bottommost layer of the metallization layers 334 is substantially level with an illustrated bottom surface (not label) of the bottommost dielectric layer of the dielectric structure 332. In such case, the illustrated bottom surface (not label) of the bottommost layer of the metallization layers 334 may be substantially coplanar to the illustrated bottom surface (not label) of the bottommost dielectric layer of the dielectric structure 332.

In some embodiments, a redistribution circuit structure 340 is formed on the illustrated bottom surface of the substrate 310, and is electrically connected to the substrate 310. In certain embodiments, the redistribution circuit structure 340 includes a dielectric structure 342 and one or more metallization layers 344 arranged therein for providing routing functionality. For example, the dielectric structure 342 includes one or more dielectric layers, such that the dielectric layers and the metallization layer 344 are sequentially formed, and one metallization layer 344 is sandwiched between two dielectric layers. As shown in FIG. 2, portions of an illustrated top surface of a topmost layer of the metallization layers 344 may be respectively exposed by a topmost portion (e.g., a topmost dielectric layer) of the dielectric structure 342, and portions of an illustrated bottom surface of a bottommost layer of the metallization layers 344 may be respectively exposed by a bottommost portion (e.g., a bottommost dielectric layer) of the dielectric structure 342; however, the disclosure is not limited thereto. For example, the illustrated top surface (not label) of the topmost layer of the metallization layers 344 is substantially level with an illustrated top surface (not label) of the topmost dielectric layer of the dielectric structure 342. In such case, the illustrated top surface (not label) of the topmost layer of the metallization layers 344 may be substantially coplanar to the illustrated top surface (not label) of the topmost dielectric layer of the dielectric structure 342. On the other hand, for example, the illustrated bottom surface (not label) of the bottommost layer of the metallization layers 344 is substantially level with an illustrated bottom surface (not label) of the bottommost dielectric layer of the dielectric structure 342. In such case, the illustrated bottom surface (not label) of the bottommost layer of the metallization layers 344 may be substantially coplanar to the illustrated bottom surface (not label) of the bottommost dielectric layer of the dielectric structure 342.

The material of the dielectric structures 332, 342 may include silicon oxide, silicon nitride, silicon oxy-nitride, or any other suitable dielectric materials, and may be formed by deposition or the like. The metallization layers 334, 344 may be or include patterned copper layers or other suitable patterned metal layers, and may be formed by electroplating or deposition. However, the disclosure is not limited thereto. Alternatively, the metallization layers 334, 344 may be formed by single or dual-damascene method. The numbers of the metallization layers and the dielectric layers included in each of the redistribution circuit structures 330, 340 is not limited thereto, and may be designated and selected based on the demand and design layout.

The through vias 320 may be connected to the portions of the illustrated bottom surface of the bottommost layer of the metallization layers 334 respectively exposed by the bottommost dielectric layer of the dielectric structure 332 and the portions of the illustrated top surface of the topmost layer of the metallization layers 344 respectively exposed by the topmost dielectric layer of the dielectric structure 342, as shown in FIG. 2. In other words, the redistribution circuit structure 330 is electrically connected to the redistribution circuit structure 340 through the through vias 320. The redistribution circuit structures 330, 340 independently may further be electrically connected to the active and/or passive devices in the substrate 310 (if any) by direct contacts therebetween. In some embodiments, through the redistribution circuit structures 330 and/or 340, the through vias 320 are electrically coupled to the active and/or passive devices in of the substrate 310 (if any).

In some embodiments, the bonding pads 352 and the dielectric layer 362 laterally covering the bonding pads 352 are formed on the redistribution circuit structure 330, where the redistribution circuit structure 330 is disposed between the substrate 310 and the dielectric layer 362 and between the substrate 310 and the bonding pads 352. For example, the bonding pads 352 are electrically coupled to the redistribution circuit structure 330 by directly contacting the metallization layers 334. For example, as shown in FIG. 2, the bonding pads 352 penetrate through and are laterally covered by the dielectric layer 362, where illustrated top surfaces (not label) of the bonding pads 352 are accessibly revealed by the dielectric layer 362. The dielectric layer 362 and the bonding pads 352 together may be referred to as a bonding layer, a bonding structure, a connecting layer or a connecting structure of the interposer 300. In some embodiments, illustrated top surfaces of the bonding pads 352 are substantially level with an illustrated top surface (not label) of the dielectric layer 362. In other words, the illustrated top surfaces of the bonding pads 352 are substantially coplanar with the illustrated top surface of the dielectric layer 362. In the disclosure, the illustrated top surfaces of the bonding pads 352 and the illustrated top surface of the dielectric layer 362 may together constitute a front side or an outermost surface of the interposer 300 for connecting to another component (e.g., the semiconductor dies 100, 200), sometimes.

An optional seed layer (not shown) may be formed before forming the bonding pads 352 and after the formation of the dielectric layers 362 so to facilitate the formation of the bonding pads 352. In some embodiments, the bonding pads 352 and the dielectric layer 362 may be formed by, but not limited to, forming a blanket layer of dielectric material over the redistribution circuit structure 330; patterning the dielectric material blanket layer to form the dielectric layer 362 having a plurality of opening holes (not labeled) penetrating through the dielectric layer 362 and accessibly revealing portions of the illustrated top surface of the exposed topmost layer of the metallization layers 334; optionally forming a blanket layer of seed layer material over the dielectric layer 342, the seed layer material blanket layer extending into the opening holes to line the opening holes and in contact with the exposed portions of the illustrated top surface of the exposed topmost layer of the metallization layers 334; forming a blanket layer of a conductive material over the seed layer material blanket layer and to fill the opening holes; patterning the conductive material blanket layer to form the bonding pads 352; using the bonding pads 352 as etching mask to pattern the seed layer material blanket layer and form a respective optional seed layer. In some embodiments, the optional seed layer is a metal layer, which may be a single layer or a composite layer comprising a plurality of sub-layers formed of different materials. In some embodiments, the optional seed layer comprises a titanium layer and a copper layer over the titanium layer, or two titanium layers and a cupper layer sandwiched between the two titanium layers. The optional seed layer may be formed using, for example, sputtering or the like. Similarly, optional seed layers (not shown) may be adapted to facilitate the formation of the metallization layers 334, if needed. The disclosure is not limited thereto.

In some embodiments, the bonding pads 354 and the dielectric layer 364 laterally covering the bonding pads 354 are formed on the redistribution circuit structure 340, where the redistribution circuit structure 340 is disposed between the substrate 310 and the dielectric layer 364 and between the substrate 310 and the bonding pads 354. For example, the bonding pads 354 are electrically coupled to the redistribution circuit structure 340 by directly contacting the metallization layers 344. For example, as shown in FIG. 2, the bonding pads 354 penetrate through and are laterally covered by the dielectric layer 364, where illustrated top surfaces (not label) of the bonding pads 354 are accessibly revealed by the dielectric layer 364. The dielectric layer 364 and the bonding pads 354 together may be referred to as a bonding layer, a bonding structure, a connecting layer or a connecting structure of the interposer 300. In some embodiments, illustrated bottom surfaces of the bonding pads 354 are substantially level with an illustrated bottom surface (not label) of the dielectric layer 364. In other words, the illustrated bottom surfaces of the bonding pads 354 are substantially coplanar with the illustrated bottom surface of the dielectric layer 364. In the disclosure, the illustrated bottom surfaces of the bonding pads 354 and the illustrated bottom surface of the dielectric layer 364 may together constitute a back side or an outermost surface of the interposer 300 for connecting to another component (e.g., connectors 621), sometimes. The formation and material of each of the bonding pads 354 and the dielectric layer 364 are similar to or substantially identical to the formation and material of each of the bonding pads 352 and the dielectric layer 362, and thus are not repeated herein for brevity.

Sometimes, the bonding pads 352 and 354 may together referred to as bonding pads 350. Sometimes, the dielectric layers 362 and 364 may together referred to as the dielectric layers 360.

Continued on FIG. 1 and FIG. 2, for example, the semiconductor dies 100 are mounted to the interposer 300 (e.g., the bonding pads 352) through the connector 611 by flip chip bonding, the semiconductor dies 200 are mounted to the interposer 300 (e.g., the bonding pads) through the connectors 612 by flip chip bonding. The connectors 611, 612 independently may include lead or be lead-free, and may include Sn-Ag, Sn-Cu, Sn-Ag-Cu, or the like. The connectors 611, 612 independently may be referred to as solder regions, conductive connectors, conductive elements. For example, the connectors 611, 612 include micro-bumps or the like. Sometimes, the connectors 611 and 612 may together referred to as connectors 610.

In some alternative embodiments, an underfill (not shown) at least fills the gaps between the semiconductor dies 100 and the interposer 300 and between the semiconductor dies 200 and the interposer 300. For example, the underfill wraps sidewalls of the connectors 611, 612. The underfill may be any acceptable material, such as a polymer, epoxy resin, molding underfill, or the like, for example. The underfill may be formed by underfill dispensing, a capillary flow process, or any other suitable method. Owing to the underfill, the bonding strength between the semiconductor dies 100, 200 and the interposer 300 is further enhanced.

After mounting the semiconductor dies 100 and 200 to the interposer 300, the semiconductor dies 100 and 200 are encapsulated in the insulating encapsulation 700, where an illustrated top surface S700 of the insulating encapsulation 700 is substantially level with the back sides S100b of the semiconductor dies 100 and the back sides S200b of the semiconductor dies 200, as shown in FIG. 1 and FIG. 2, in some embodiments. In other words, the illustrated top surface S700 of the insulating encapsulation 700 may be substantially coplanar to the back sides S100b of the semiconductor dies 100 and the back sides S200b of the semiconductor dies 200. That is, the back sides S100b of the semiconductor dies 100 and the back sides S200b of the semiconductor dies 200 is accessibly revealed by the insulating encapsulation 700. Alternatively, the semiconductor dies 100 and 200 are not exposed by the illustrated top surface S700 of the insulating encapsulation 700.

For example, the insulating encapsulation 700 at least fills up the gaps between the semiconductor dies 100, 200 and covers the interposer 300 exposed therefrom. In some embodiments, the insulating encapsulation 700 is a molding compound formed by a molding process. In some embodiments, the insulating encapsulation 700 include polymers (such as epoxy resins, phenolic resins, silicon-containing resins, or other suitable resins), dielectric materials, or other suitable materials. In an alternative embodiment, the insulating encapsulation 700 may include an acceptable insulating encapsulation material. The insulating encapsulation 700 may further include inorganic filler or inorganic compound (e.g., silica, clay, and so on) which can be added therein to optimize coefficient of thermal expansion (CTE) of the insulating encapsulation 700, the disclosure is not limited thereto. The insulating encapsulation 700 may be referred to as an encapsulant, a dielectric encapsulation, or an encapsulation. For example, the insulating encapsulation 700 is formed by, but not limited to, over-molding the semiconductor dies 100, 200 by an insulating encapsulation material, and patterning the insulating encapsulation material to form the insulating encapsulation 700. The insulating encapsulation material may be patterned by a planarizing process until obtaining a substantially flat and planar surface therefrom (e.g., S700). Owing to the insulating encapsulation 700, the semiconductor dies 100, 200 are protected from the damages caused by the external contacts.

The planarizing process is performed by mechanical grinding, CMP, etching or combinations thereof, for example. The etching may include dry etching, wet etching, or a combination thereof. After the planarizing process, a cleaning process may be optionally performed to clean and remove the residue generated from the planarizing process. However, the disclosure is not limited thereto, and the planarizing process may be performed through any other suitable method. Up to here, the package P1 is manufactured, where the package P1 is a chip-on-wafer (CoW) package.

Continued on FIG. 1 and FIG. 2, the package P1 is mounted to the substrate 500 through the connectors 621 by flip-chip bonding, and the semiconductor devices 400 are mounted to the substrate 500 through connectors 622 by flip-chip bonding. The connectors 621, 622 independently may be referred to as solder regions, conductive connectors, conductive elements. For example, the connectors 621, 622 include controlled collapse chip connection (C4) bumps (for example, which may have, but not limited to, a size of about 80 μm) or the like. Sometimes, the connectors 621 and 622 may together referred to as the connectors 620.

For example, in a vertical projection on the substrate 500 along the direction Z, a projection of the package P1 has a rectangular shape with edges E1, E2, E3 and E4, where the semiconductor dies 100 and 200 included in the package P1 are arranged into a matrix form, see FIG. 1. In some embodiments, the semiconductor devices 400 are laterally arranged next to the package P1 by a non-zero distance in the direction X and/or Y. As shown in FIG. 1, the semiconductor devices 400 may surround the package P1. For example, the semiconductor devices 400 includes a plurality of semiconductor devices 400a arranged along the edge E1 of the package P1, a plurality of semiconductor devices 400b arranged along the edge E2 of the package P1, a plurality of semiconductor devices 400c arranged along the edge E3 of the package P1, and a plurality of semiconductor devices 400d arranged along the edge E4 of the package P1. In some embodiments, the semiconductor devices 400 include optical devices or optical dies. For example, the semiconductor devices 400 independently include a compact universal photonic engine (COUPE), which has the electrical IC (EIC)-to-photonic IC (PIC) integration with the electrical interface designed to minimize the EIC-PIC coupling loss. That is, the semiconductor devices 400 are configurated to couple with fabric array units (not shown) to transmit optical signals to the semiconductor package SP1 from an external device/component and/or transmit optical signals to an external device/component from the semiconductor package SP1. Alternatively, the semiconductor devices 400 may be arranged along three sides of the package P1, such as the edges, E1, E2 and E3; E2, E3 and E4; E1, E3 and E4; or E1, E2 and E4. Alternatively, the semiconductor devices 400 may be arranged along two sides of the package P1, such as the edges, E1 and E2; E2 and E3; E3 and E4; E1 and E4; E1 and E3; or E2 and E4. Alternatively, the semiconductor devices 400 may be arranged along one side of the package P1, such as the edge E1, E2, E3, or E4, only. The disclosure is not limited thereto; alternatively, in the vertical projection on the substrate 500 along the direction Z, the projection of the package P1 may have a square shape or any other suitable shape.

Alternatively or in addition to, an IPD die, a VR die, a LSI die with or without DTC features, a local silicon interconnect die with multi-tier functions such as electrical and/or optical network circuit interfaces, IPD, VR, DTC, or the like may be included to substitute one or some of the semiconductor devices 400 or be further adopted.

In some embodiments, the substrate 500 includes a body 540, metallization layers 530 and vias (not shown) interconnected therebetween and disposed in the body 540, and a plurality of bonding pads 510, 520 connected to the metallization layers 530 and vias. As shown in FIG. 2, the body 540 has a surface S540t and a surface S540b opposing to the surface S540t, where the bonding pads 510 are accessibly revealed by the surface S540t of the body 540, and the bonding pads 520 are accessibly revealed by the surface S540b of the body 540. The body 540 may be made of a semiconductor material such as silicon, germanium, diamond, or the like. In some embodiments, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. In some alternative embodiments, the body 540 is a SOI substrate, where the SOI substrate may include a layer of a semiconductor material such as epitaxial silicon, germanium, silicon germanium, SOI, silicon germanium on insulator (SGOI), or combinations thereof. In further alternative embodiments, the body 540 is based on an insulating core, such as a fiberglass reinforced resin core. One example core material is fiberglass resin such as flame retardant class 4 (FR4). Alternatives for the core material may include bismaleimide triazine (BT) resin, or alternatively, other printed circuit board (PCB) materials or films. In yet further alternative embodiments, the body 540 is a build-up film such as Ajinomoto build-up film (ABF) or other suitable laminates. In one embodiment, the body 540 may include active and/or passive devices (not shown), such as transistors, capacitors, resistors, combinations thereof, or the like which may be used to generate the structural and functional requirements of the design for the semiconductor package. The active and/or passive devices may be formed using any suitable methods. However, the disclosure is not limited thereto; in an alternative embodiment, the body 540 may be substantially free of active and/or passive devices.

The metallization layers 530 and vias together form a functional circuitry providing routing for the substrate 500. The metallization layers 530 and vias embedded in the body 540 may be formed of alternating layers of dielectric (e.g., low-k dielectric material) and conductive material (e.g., copper) with vias interconnecting the layers of conductive material and may be formed through any suitable process (such as deposition, damascene, dual damascene, or the like). The bonding pads 510, 520 are used to provide electrical connection with external component(s) for the substrate 500. In some embodiments, the bonding pads 510, 520 are located at two opposite sides of the body 540 along the direction Z and electrically connected to each other through the metallization layers 530 and vias. The formation and material of the bonding pads 510, 520 may be similar to or substantially identical to the formation and material of the bonding pads 352, 354, and thus are not repeated herein for brevity. As shown in FIG. 2, for example, the package P1 is connected to some of the bonding pads 510 of the substrate 500 through the connectors 621, and the semiconductor devices 400 are connected to some of the bonding pads 510 through the connectors 622. In addition, the substrate 500 is considered as a circuit structure.

In some embodiments, as shown in FIG. 2, an underfill 710 at least fills the gaps between the package P1 and the substrate 500 and wraps sidewalls of the connectors 621, where the underfill 710 covers the back side of the interposer 300 and portions of the surface S540 of the substrate 500 and further extends onto a portion of a sidewall of the interposer 300. On the other hand, for example, an underfill 720 at least fills the gaps between the semiconductor devices 400 and the substrate 500 and wraps sidewalls of the connectors 621, where the underfill 720 covers the back side of the interposer 300 and other portions of the surface S540 of the substrate 500 and further extends onto a portion of a sidewall of each of the semiconductor devices 400.

In some embodiments, a plurality of connectors 630 are formed over the bonding pads 520 at the surface S540b of the substrate 500, where the connectors 630 are electrically connected to the substrate 500. For example, the package P1 is electrically coupled to some of the connectors 630 through the connectors 621 (e.g., connecting to the bonding pads 654 of the interposer 300) and the substrate 500, and the semiconductor devices 400 are electrically coupled to some of the connectors 630 through the connectors 622 (e.g., connecting to bonding pads 410 of the semiconductor devices 400) and the substrate 500. The connectors 630 includes a ball grid array (BGA) bumps (for example, which may have, but not limited to, a size of about 400 μm), electroless nickel-immersion gold technique (ENIG) formed bumps, electroless nickel-electroless palladium-immersion gold technique (ENEPIG) formed bumps, or the like, in some embodiments. The connectors 630 may be referred to as conductive terminals, conductive connectors, conductive elements of the substrate 500 for external connections (e.g., to an motherboard or the like).

Referring to FIG. 3 through FIG. 5 in conjunction with FIG. 15 through FIG. 17, in some embodiments, a heat dissipating element 1010A is provided and disposed on the structure depicted in FIG. 1 and FIG. 2. For example, the heat dissipating element 1010A is overlapped with the semiconductor devices 400 and the substrate 500 and offset from the package P1, as shown in FIG. 4. For example, the heat dissipating element 1010A is in a form of a continuous frame and includes a plurality of supporting blocks 1011, a plurality of outer bars 1012 connecting to the supporting blocks 1011, and a plurality of inner bars 1013 connecting to the supporting blocks 1011 and surrounded by the outer bars 1012, where a shape of the continuous frame is corresponding to the shape of the package P1 in the vertical projection (e.g., X-Y plane) along the direction Z. In some embodiments, the inner bars 1013 include an inner bar 1013a disposed next to the edge E1 of the package P1 (e.g., with a non-zero distance) and overlapped with the semiconductor devices 400a, an inner bar 1013b disposed next to the edge E2 of the package P1 (e.g., with a non-zero distance) and overlapped with the semiconductor devices 400b, an inner bar 1013c disposed next to the edge E3 of the package P1 (e.g., with a non-zero distance) and overlapped with the semiconductor devices 400c, and an inner bar 1013d disposed next to the edge E4 of the package P1 (e.g., with a non-zero distance) and overlapped with the semiconductor devices 400d. In some embodiments, the outer bars 1012 include an outer bar 1012a disposed next to a side of the inner bar 1013a (e.g., with a non-zero distance) opposing to the package P1, an outer bar 1012b disposed next to a side of the inner bar 1013b (e.g., with a non-zero distance) opposing to the package P1, an outer bar 1012c disposed next to a side of the inner bar 1013c (e.g., with a non-zero distance) opposing to the package P1, and an outer bar 1012d disposed next to a side of the inner bar 1013d (e.g., with a non-zero distance) opposing to the package P1. As shown in FIG. 3, for example, the supporting blocks 1011 include a supporting block 1011a having a first side connected to the inner bar 1013a and the outer bar 1012a and a second side connected to the inner bar 1013b and the outer bar 1012b, a supporting block 1011b having a first side connected to the inner bar 1013b and the outer bar 1012b and a second side connected to the inner bar 1013c and the outer bar 1012c, a supporting block 1011c having a first side connected to the inner bar 1013c and the outer bar 1012c and a second side connected to the inner bar 1013d and the outer bar 1012d, and a supporting block 1011d having a first side connected to the inner bar 1013d and the outer bar 1012d and a second side connected to the inner bar 1013a and the outer bar 1012a. That is, as shown in FIG. 15, a first end of one inner bar 1013 and a first end of a respective one outer bar 1012 are connected to a side of a respective one supporting block 1011, and a second end of the one inner bar 1013 (opposing to the first end thereof) and a second end of the respective one outer bar 1012 (opposing to the first end thereof) are connected to a side of another respective supporting block 1011, where the inner bars 1013 and the outer bars 1012 are spatially separated from each other. In other words, the inner bars 1013 and the outer bars 1012 of the heat dissipating element 1010A are not in physical contact with each other. In some embodiments, the inner bars 1013 and portions of the supporting blocks 1011 together form a frame structure F1, and the outer bars 1012 and portions of the supporting blocks 1011 together form a frame structure F2, where the frame structure F1 is surrounded by the frame structure F2. With such frame structure of the thermal dissipating element 1010A, a stress buffer to the semiconductor package SP1 is obtained. The manufacture of the semiconductor package SP1 is compatible to the current and/or advanced manufacturing processes.

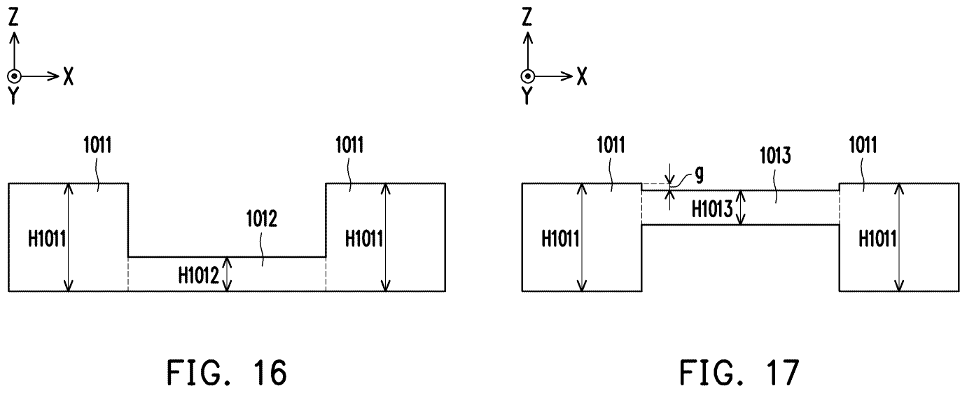

As shown in FIG. 15 through FIG. 17, for example, each inner bar 1013 has a width D4 (e.g., a shortest lateral size as measured in the direction X or Y) approximately ranging from 3 mm to 15 mm and a thickness H1013 (as measured in the direction Z) approximately ranging from 1.5 mm to 4.5 mm, each outer bar 1012 has a width D3 (e.g., a shortest lateral size as measured in the direction X or Y) greater than 3 mm and a thickness H1012 (as measured in the direction Z) approximately ranging from 0.5 mm to 1.0 mm, and each supporting block 1011 has a first lateral size D1 (e.g., as measured in one of the direction X or Y) being greater than or substantially equal to a sum of the width D4 and the width D3, a second lateral size D2 (e.g., as measured in other one of the direction X or Y) being greater than or substantially equal to a sum of the width D4 and the width D3, and a thickness H1011 (as measured in the direction Z) approximately ranging from 3 mm to 5 mm. In some embodiments, a minimum distance g between an edge of one inner bar 1013 to an edge of the respective one supporting block 1011 is greater than or substantially equal to zero. For example, the minimum distance g is non-zero, also see the cross-sectional view of FIG. 17 taken along a line EE′ depicted in FIG. 15. In some embodiments, a minimum distance between an edge of one outer bar 1012 to an edge of the respective one supporting block 1011 is substantially equal to zero. For example, an illustrated bottom surface of the outer bar 1012 is substantially level with and substantially coplanar to illustrated bottom surfaces of the supporting blocks 1011 connected thereto, see the cross-sectional view of FIG. 16 taken along a line DD′ depicted in FIG. 15. In some embodiments, the thickness H1011 of the supporting blocks 1011 is greater than the thickness H1012 of the outer bar 1012 and the thickness H1013 of the inner bars 1013, as shown in FIG. 15 through FIG. 17. In some embodiments, all of the inner bars 1013 have the same width D4, with or without same thickness (e.g., H1013). Alternatively, some of the inner bars 1013 have different width D4, with or without same thickness (e.g., H1013). In some embodiments, all of the outer bars 1012 have the same width D3, with or without same thickness (e.g., H1012). Alternatively, some of the outer bars 1012 have different width D3, with or without same thickness (e.g., H1012). In some embodiments, all of the supporting blocks 1011 have the same lateral sizes D1 and D2, with or without same thickness (e.g., H1011). Alternatively, some of the supporting blocks 1011 have different lateral sizes D1 and/or different lateral sizes D2, with or without same thickness (e.g., H1011).

Back to FIG. 3 and FIG. 4, in some embodiments, the inner bars 1013 (e.g., 1013a, 1013b, 1013c, 1013d) of the heat dissipating element 1010A are disposed on and thermally coupled to the semiconductor devices 400 (e.g., 400a, 400b, 400c, 400d) through a thermal interface material (TIM) 830, respectively. The thermal interface material 830 may include any suitable thermally conductive material such as a polymer having a good thermal conductivity, which may be between about 3 W/m·K to about 10 W/m·K or more. The disclosure does not specifically limit a thickness of the thermal interface material 830 as long as the thermal interface material 830 is thick enough to sufficiently dissipating heat from the semiconductor devices 400 to the heat dissipating element 1010A.

On the other hand, the outer bars 1012 (e.g., 1012a, 1012b, 1012c, 1012d) and the supporting blocks 1011 (e.g., 1011a, 1011b, 1011c, 1011d) of the heat dissipating element 1010A are disposed on the substrate 500 through a bonding element 820, for example, as shown in FIG. 3 through FIG. 5. A material of the bonding element 820 is not particularly limited, and may be chosen as a function of a material used for adhering the substrate 500 and the heat dissipating element 1010A (e.g. the outer bars 1012 and the supporting blocks 1011), where the bonding element 820 has to secure the substrate 500 and the heat dissipating element 1010A together. For example, a material of the bonding element 820 includes a thermo-curable adhesive, photocurable adhesive, thermally conductive adhesive, thermosetting resin, waterproof adhesive, lamination adhesive or a combination thereof. In some embodiments, the material of the bonding element 820 includes a thermally conductive adhesive. For another example, the bonding element 820 includes a die attach film (DAF). According to the type of material used, the bonding element 820 may be formed by deposition, lamination, printing, plating, or any other suitable technique. In certain embodiments, depending on the material of the bonding element 820, the substrate 500 may be thermally coupled to the heat dissipating element 1010A through the bonding element 820.

The heat dissipating element 1010A may be formed by, but not limited to, forging and stamping, CNC processes, punching press, shaping, milling or the like. The heat dissipating element 1010A, for example, has a high thermal conductivity between about 200 W/m·K to about 400 W/m·K or more, and is formed using a metal, a metal alloy, and the like. However, the disclosure is not limited thereto. In some embodiments, the supporting blocks 1011, the outer bars 1012 and the inner bars 1013 of the heat dissipating element 1010A are formed as an integral piece. The heat dissipating element 1010A has a one-piece structure.

Referring to FIG. 6 through FIG. 8, in some embodiments, a thermal dissipating element 1020A is provided and disposed over the structure depicted in FIG. 3 through FIG. 5 to form the semiconductor package SP1. For example, the heat dissipating element 1020A includes a first portion 1021 and a second portion 1022A surrounding to the first portion 1021. As shown in FIG. 7 and FIG. 8, the first portion 1021 of the thermal dissipating element 1020A is disposed on and thermally coupled to the package P1 through a thermal interface material (TIM) 810, and the second portion 1021 of the thermal dissipating element 1020A is disposed on and thermally coupled to the heat dissipating element 1010A through a thermal interface material (TIM) 840. The thermal interface materials 810, 840 independently may include any suitable thermally conductive material such as a polymer having a good thermal conductivity, which may be between about 3 W/m·K to about 10 W/m·K or more. The disclosure does not specifically limit a thickness of the thermal interface materials 810, 840 as long as the thermal interface materials 810, 840 are thick enough to sufficiently dissipating heat from the package P1 and the heat dissipating element 1010A to the heat dissipating element 1020A. In some embodiments, the thermal conductivity of the thermal interface material 810 is greater than or substantially equal to the thermal conductivity of the thermal interface material 840. In some embodiments, the thermal conductivity of the thermal interface material 810 is greater than or substantially equal to the thermal conductivity of the thermal interface material 830. For example, the thermal conductivity of the thermal interface material 810 is greater than the thermal conductivity of the thermal interface material 830. Due to the difference in the thermal conductivities of the thermal interface materials 810 and 830, the thermal solution of the semiconductor package SP1 is optimized. In some embodiments, the thermal conductivity of the thermal interface material 840 is greater than, less than or substantially equal to the thermal conductivity of the thermal interface material 830.

In some embodiments, a thickness (not label, as measured in the direction Z) of the first portion 1021 is greater than a thickness (not label, as measured in the direction Z) of the second portion 1022A, as shown in FIG. 7. However, the disclosure is not limited thereto, alternatively, a thickness (not label, as measured in the direction Z) of the first portion 1021 is substantially equal to a thickness (not label, as measured in the direction Z) of the second portion 1022A. In some embodiments, the heat dissipating element 1010A and the heat dissipating element 1020A may together be referred to as a heat dissipating module 1000A. As shown in FIG. 6 through FIG. 8, the second portion 1022A of the heat dissipating element 1020A is overlapped with the heat dissipating element 1010A, for example. In some embodiments, the semiconductor package SP1 is a chip-on-wafer-on-substrate (CoWoS) package equipped with optics for optical signal transmission.

Alternatively, the thermal interface material 840 may be omitted, see the semiconductor package SP2 shown in FIG. 9 through FIG. 11. For example, the second portion 1022A of the heat dissipating element 1020A is overlapped with the heat dissipating element 1010A, and there is an air gap between the second portion 1022A of the heat dissipating element 1020A and the heat dissipating element 1010A.

The disclosure is not limited thereto. In an alternative embodiment, the heat dissipating element 1020A is substituted by an heat dissipating element 1020B, where the heat dissipating element 1020B is not overlapped with the heat dissipating element 1010A, see a heat dissipating module 1000B of the semiconductor package SP3 shown in FIG. 9 through FIG. 11. The heat dissipating module 1000B includes a heat dissipating element 1010A and the dissipating element 1020B, where the heat dissipating element 1020B includes a first portion 1021 and a second portion 1022B surrounding the first portion 1021, and the second portion 1022B of the heat dissipating element 1020B is not overlapped with the heat dissipating element 1010A, for example.

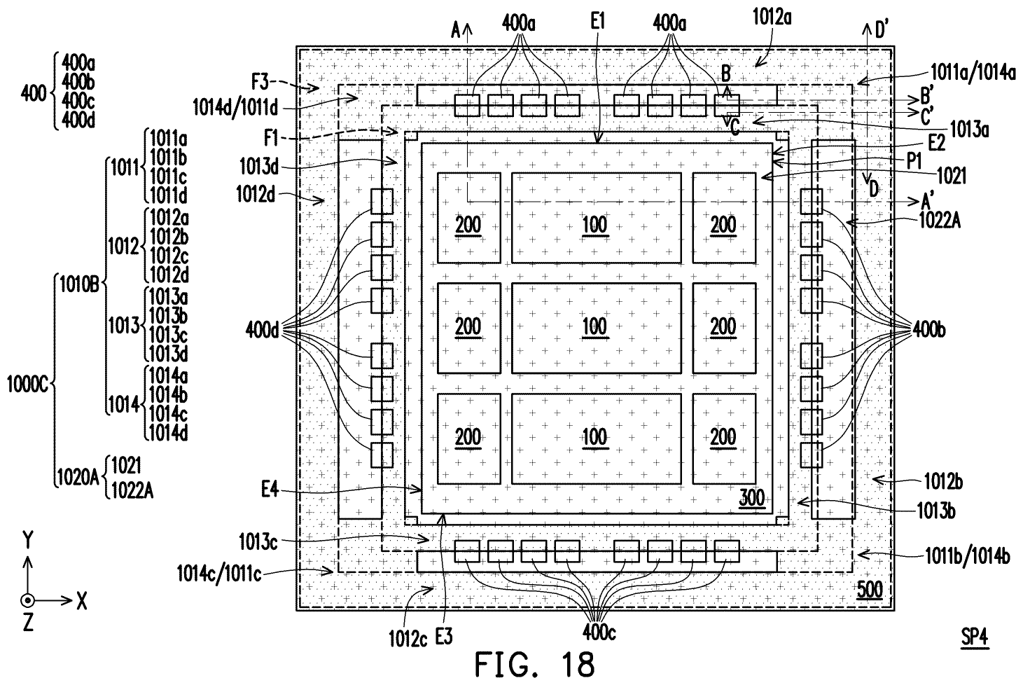

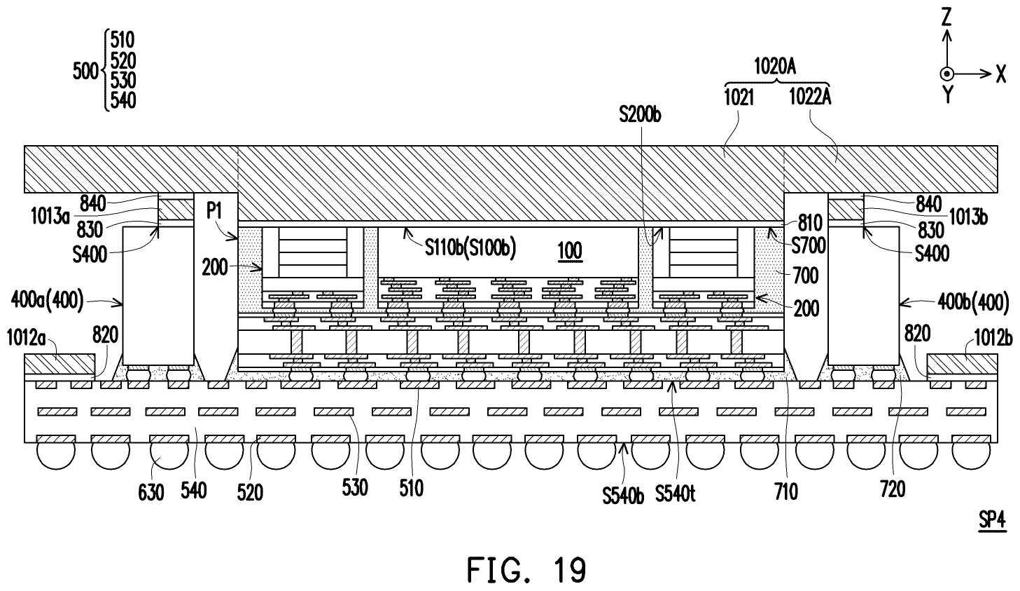

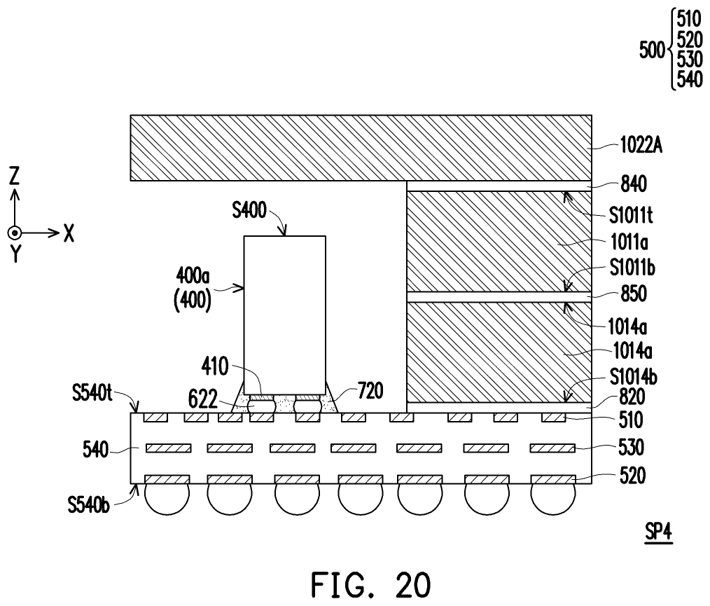

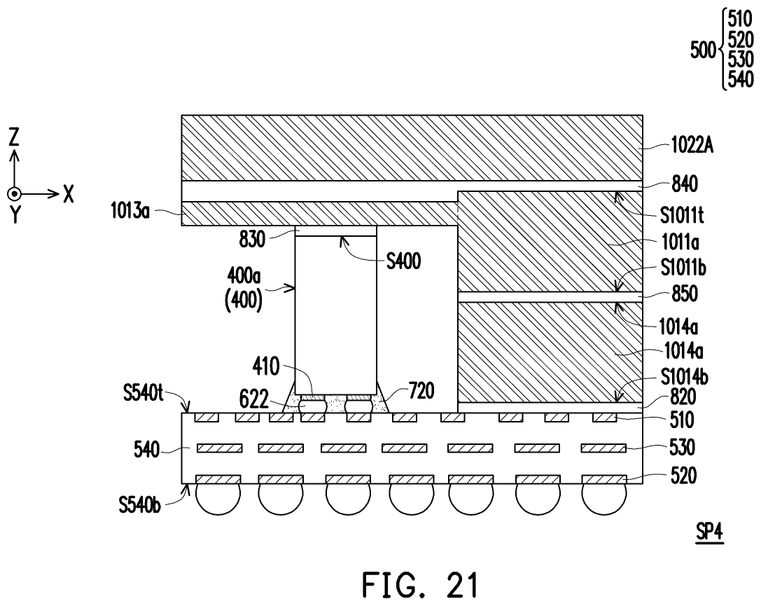

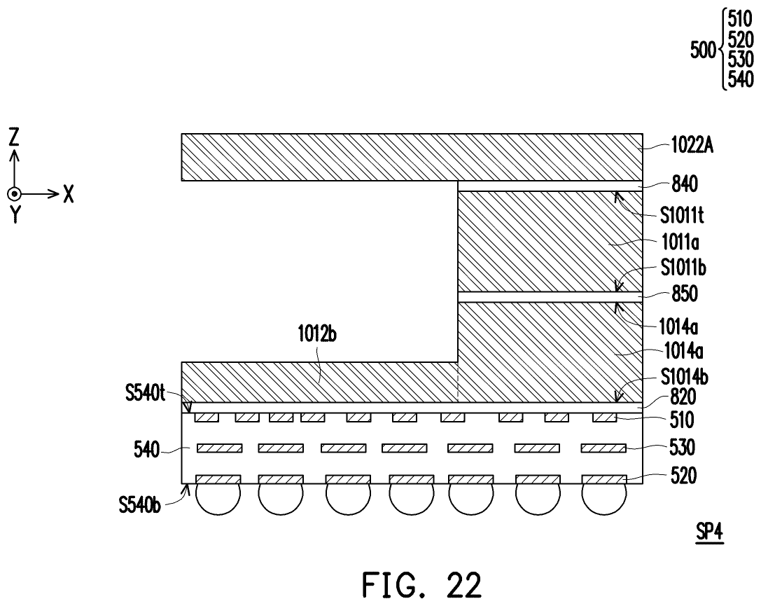

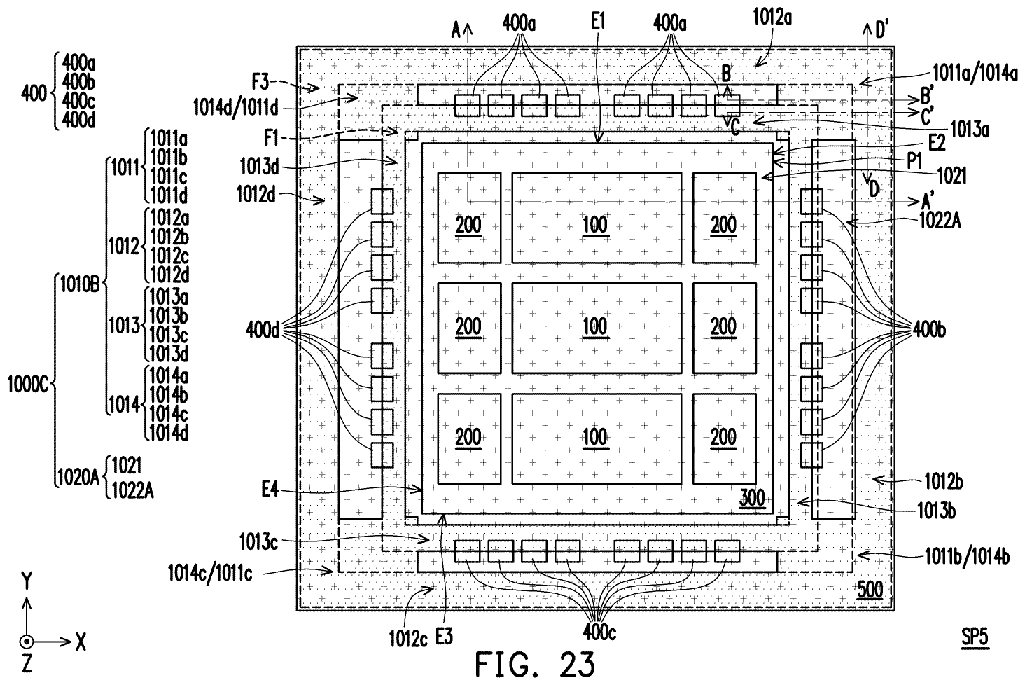

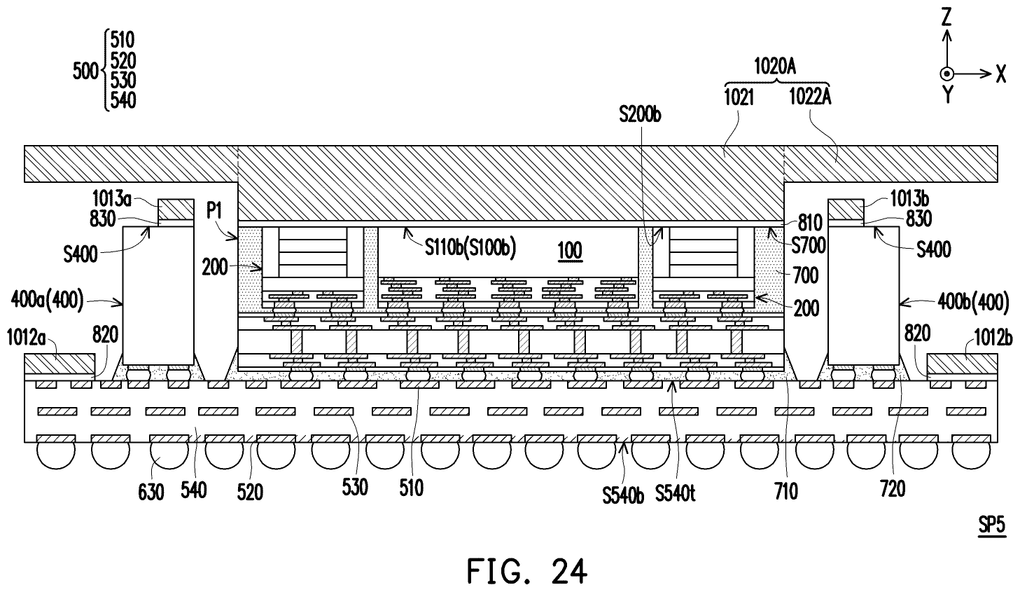

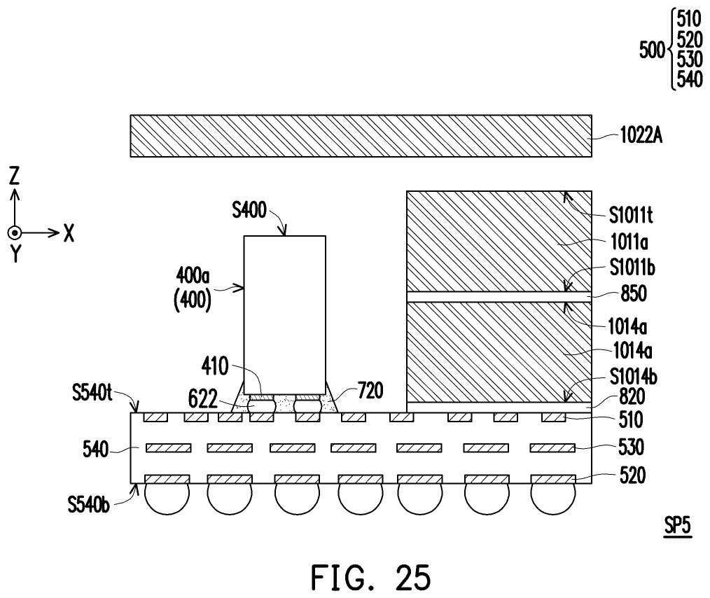

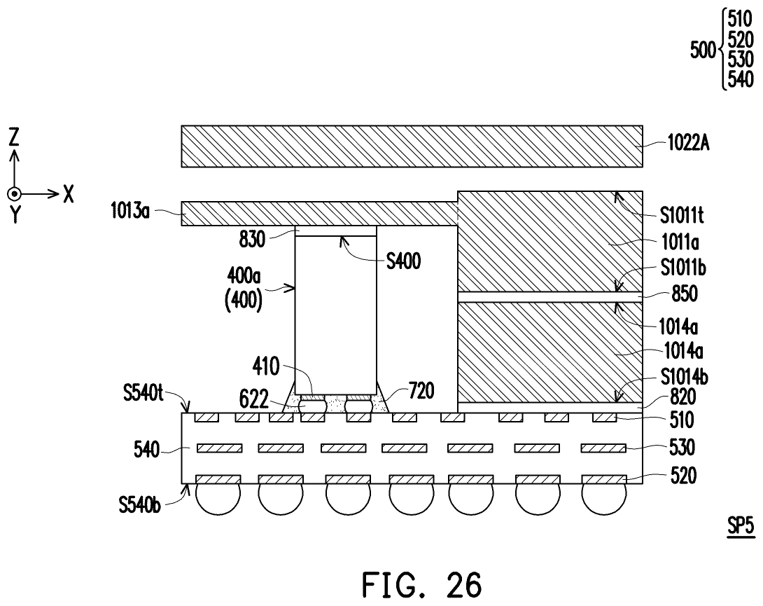

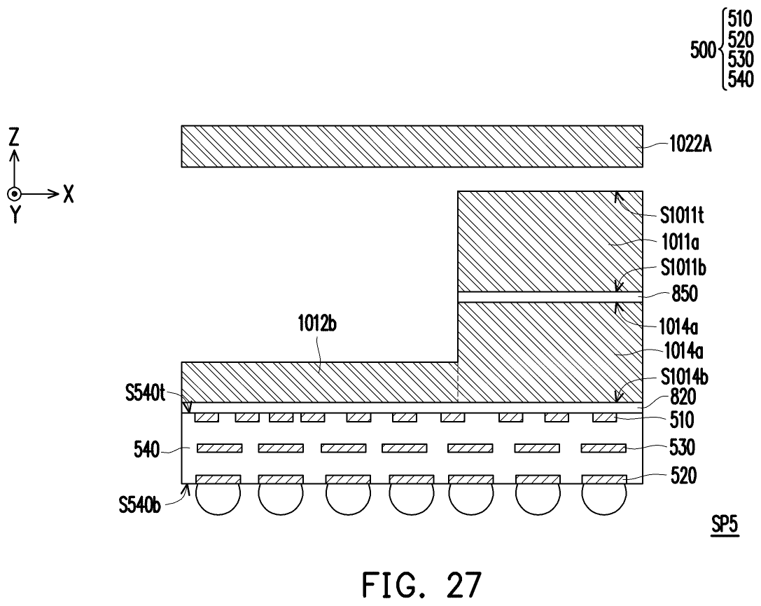

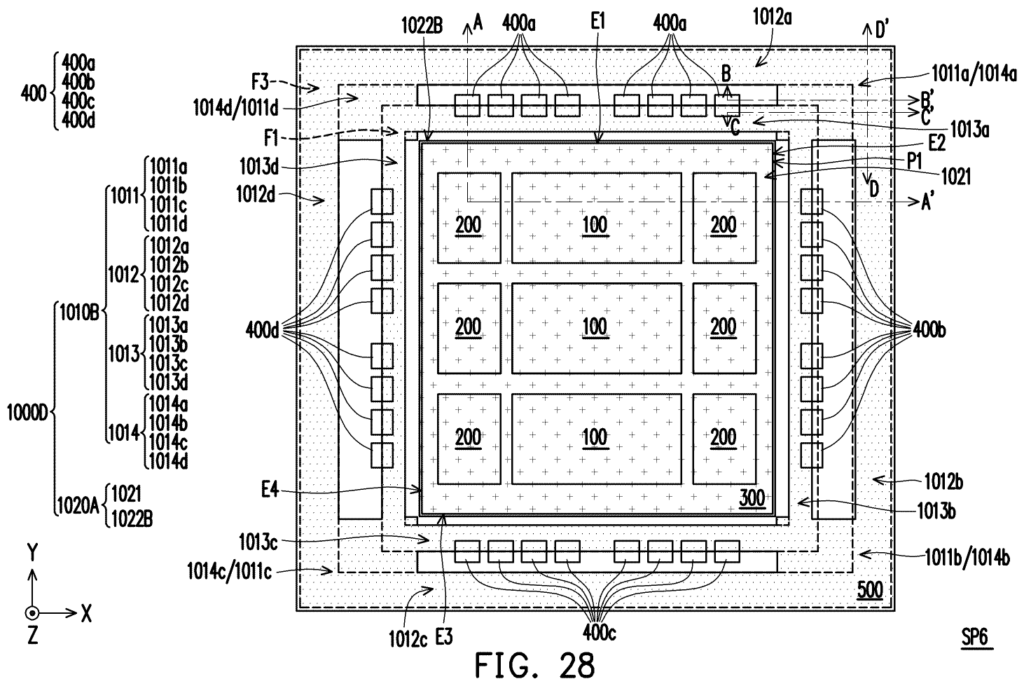

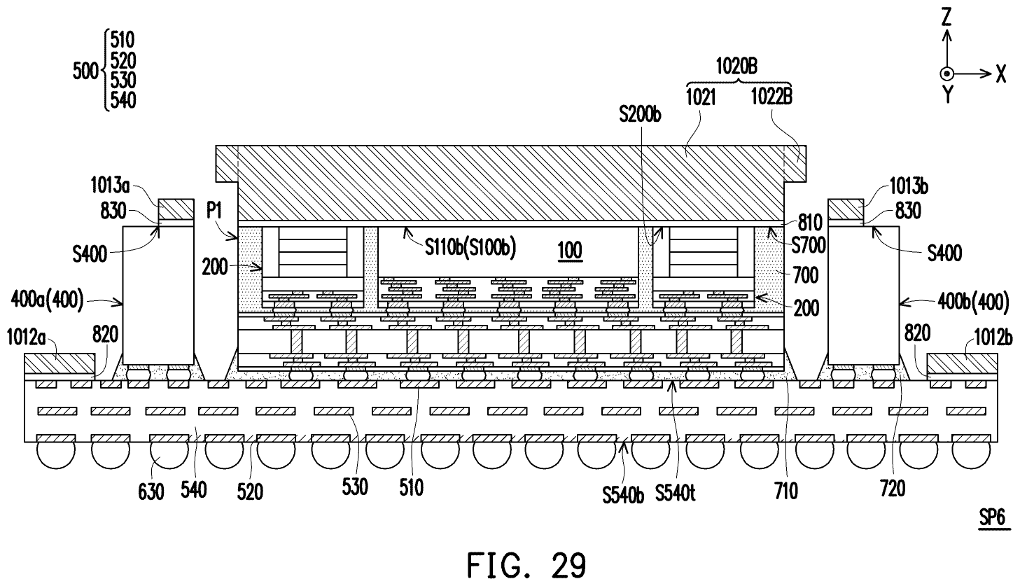

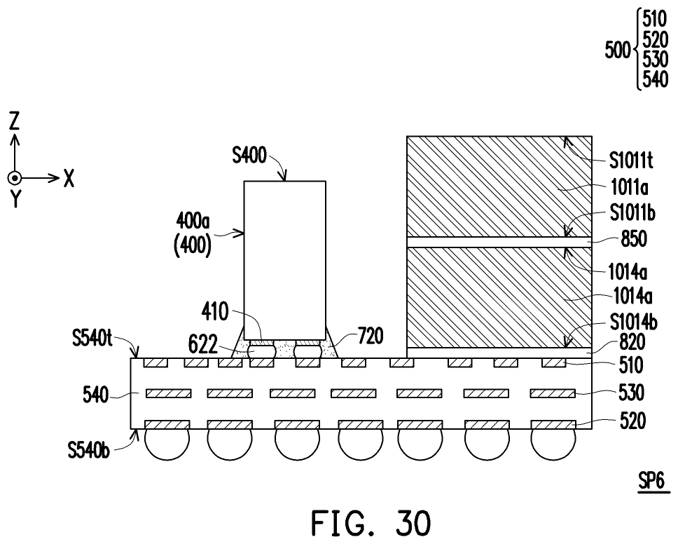

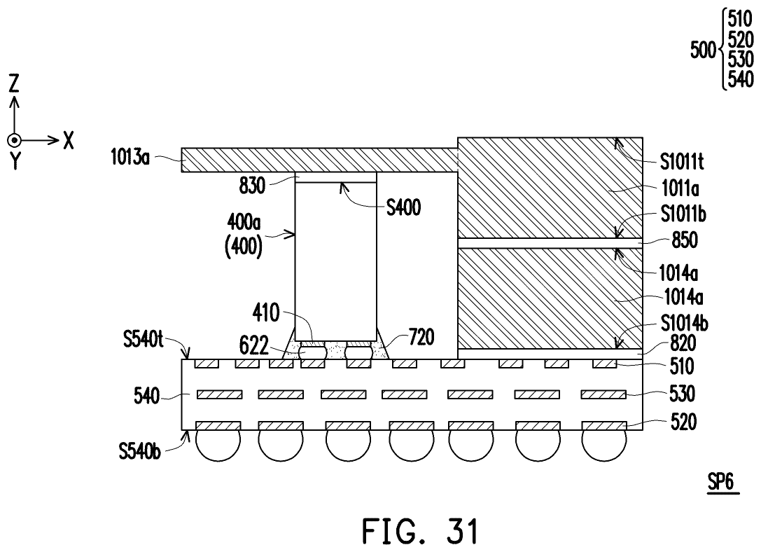

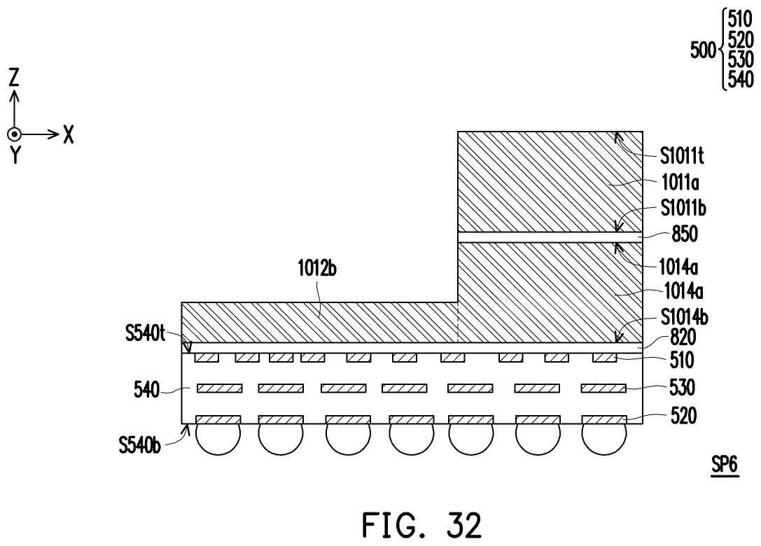

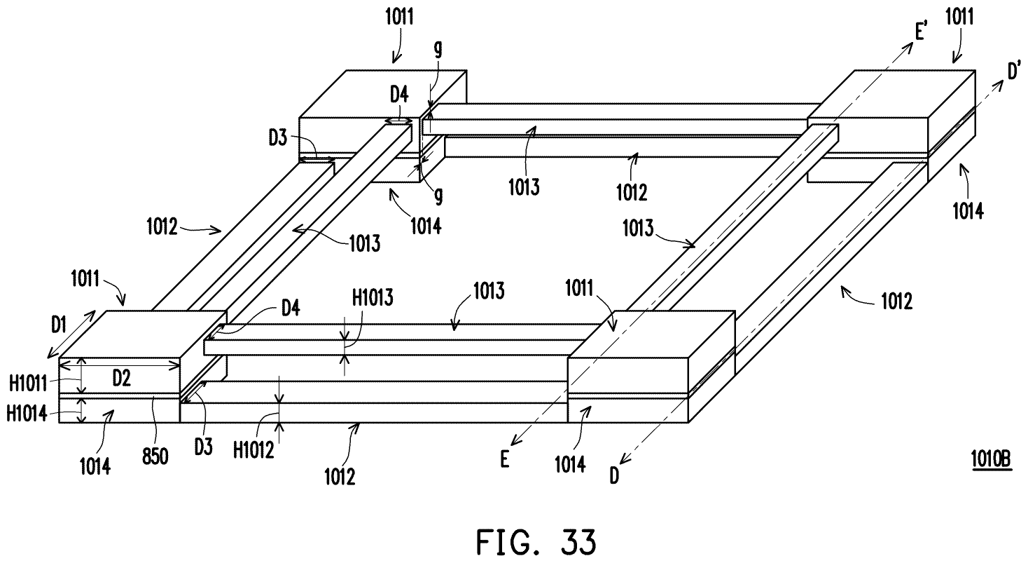

FIG. 18 through FIG. 22 are schematic cross-sectional views or plane views of a semiconductor package (e.g., SP4) in accordance with some embodiments of the disclosure, where the cross-sectional view of FIG. 19 is taken along the line AA′ depicted in the plane view of FIG. 18, the cross-sectional views of FIG. 20 is taken along the line BB′ depicted in the plane view of FIG. 18, the cross-sectional views of FIG. 21 is taken along a line CC′ depicted in the plane view of FIG. 18, and the cross-sectional views of FIG. 22 is taken along a line DD′ depicted in the plane view of FIG. 18. FIG. 23 through FIG. 27 are schematic cross-sectional views or plane views of a semiconductor package (e.g., SP5) in accordance with some alternative embodiments of the disclosure, the cross-sectional view of FIG. 24 is taken along the line AA′ depicted in the plane view of FIG. 23, the cross-sectional views of FIG. 25 is taken along the line BB′ depicted in the plane view of FIG. 23, the cross-sectional views of FIG. 26 is taken along the line CC′ depicted in the plane view of FIG. 23, and the cross-sectional views of FIG. 27 is taken along the line DD′ depicted in the plane view of FIG. 23. FIG. 28 through FIG. 32 are schematic cross-sectional views or plane views of a semiconductor package (e.g., SP6) in accordance with some alternative embodiments of the disclosure, where the cross-sectional view of FIG. 29 is taken along the line AA′ depicted in the plane view of FIG. 28, the cross-sectional views of FIG. 30 is taken along the line BB′ depicted in the plane view of FIG. 28, the cross-sectional views of FIG. 31 is taken along the line CC′ depicted in the plane view of FIG. 28, and the cross-sectional views of FIG. 32 is taken along the line DD′ depicted in the plane view of FIG. 28. FIG. 33 through FIG. 35 are schematic cross-sectional views or three-dimensional views of a frame structure of a thermal dissipating element (e.g., 1010B) in a semiconductor package (e.g., SP4, SP5, or SP6) in accordance with some embodiments of the disclosure. The elements similar to or substantially the same as the elements described previously will use the same reference numbers, and certain details or descriptions (e.g., the materials, formation processes, positioning configurations, etc.) of the same elements would not be repeated herein. The semiconductor package SP4 of FIG. 18 through FIG. 22 is similar to the semiconductor package SP1 of FIG. 6 through FIG. 8, a difference is that, in the semiconductor package SP4 of FIG. 18 through FIG. 22, a heat dissipating element 1010B is adopted, instead of heat dissipating element 1010A.

Referring to FIG. 18 through FIG. 22 in conjunction with FIG. 33 through FIG. 35, in some embodiments, the semiconductor package SP4 includes a substrate 500, a package P1 disposed on and electrically coupled to the substate 500 through connectors 621, a plurality of semiconductor devices 400 disposed on and electrically coupled to the substate 500 through connectors 622 and laterally next to the package P1, and a heat dissipating module 1000C disposed over and connected to the substrate 500 through a bonding element 820, where the heat dissipating module 1000C is disposed over and thermally coupled to the package P1 through a thermal interface material 810 and disposed over and thermally coupled to the semiconductor devices 400 through a thermal interface material 830. For example, the heat dissipating module 1000C includes a heat dissipating element 1010B and a heat dissipating element 1020A (including a first portion 1021 and a second portion 1022A), where the heat dissipating element 1010B and the heat dissipating element 1020A are connected to and thermally coupled to each other through a thermal interface material 840. The details, formations and materials of the substrate 500, the package P1, the semiconductor devices, the connectors 621 and 622, the thermal interface materials 810, 830, 840, the bonding material 820, and the heat dissipating element 1020A (including 1021 and 1022A) have been previously discussed in FIG. 1 through FIG. 8, and thus are not repeated herein for brevity. In some embodiments, the thermal interface material 810 is different from the thermal interface material 830, such as the thermal conductivity of the thermal interface material 810 is greater than the thermal conductivity of thermal interface material 830. Due to the difference in the thermal conductivities of the thermal interface materials 810 and 830, the thermal solution of the semiconductor package SP4 is optimized.

For example, the heat dissipating element 1010B is overlapped with the semiconductor devices 400 and the substrate 500 and offset from the package P1, as shown in FIG. 18 and FIG. 19. For example, the heat dissipating element 1010B is in a form of a continuous frame and includes a plurality of supporting blocks 1011, a plurality of outer bars 1012, a plurality of inner bars 1013 and a plurality of supporting blocks 1014, where the outer bars 1012 are connected to the supporting blocks 1014, and the inner bars 1013 are connected to the supporting blocks 1011, where a shape of the continuous frame is corresponding to the shape of the package P1 in the vertical projection (e.g., X-Y plane) along the direction Z. In some embodiments, the inner bars 1013 include an inner bar 1013a disposed next to the edge E1 of the package P1 (e.g., with a non-zero distance) and overlapped with the semiconductor devices 400a, an inner bar 1013b disposed next to the edge E2 of the package P1 (e.g., with a non-zero distance) and overlapped with the semiconductor devices 400b, an inner bar 1013c disposed next to the edge E3 of the package P1 (e.g., with a non-zero distance) and overlapped with the semiconductor devices 400c, and an inner bar 1013d disposed next to the edge E4 of the package P1 (e.g., with a non-zero distance) and overlapped with the semiconductor devices 400d. In some embodiments, the outer bars 1012 include an outer bar 1012a disposed next to a side of the inner bar 1013a (e.g., with a non-zero distance) opposing to the package P1, an outer bar 1012b disposed next to a side of the inner bar 1013b (e.g., with a non-zero distance) opposing to the package P1, an outer bar 1012c disposed next to a side of the inner bar 1013c (e.g., with a non-zero distance) opposing to the package P1, and an outer bar 1012d disposed next to a side of the inner bar 1013d (e.g., with a non-zero distance) opposing to the package P1. As shown in FIG. 18 and FIG. 33, for example, the supporting blocks 1011 include a supporting block 1011a having a first side connected to the inner bar 1013a and a second side connected to the inner bar 1013b, a supporting block 1011b having a first side connected to the inner bar 1013b and a second side connected to the inner bar 1013c, a supporting block 1011c having a first side connected to the inner bar 1013c and a second side connected to the inner bar 1013d, and a supporting block 1011d having a first side connected to the inner bar 1013d and a second side connected to the inner bar 1013a. On the other hand, for example, the supporting blocks 1014 include a supporting block 1014a having a first side connected to the outer bar 1012a and a second side connected to the outer bar 1012b, a supporting block 1014b having a first side connected to the outer bar 1012b and a second side connected to the outer bar 1012c, a supporting block 1014c having a first side connected to the outer bar 1012c and a second side connected to the outer bar 1012d, and a supporting block 1014d having a first side connected to the outer bar 1012d and a second side connected to the outer bar 1012a.

That is, as shown in FIG. 33, a first end of one inner bar 1013 is connected to a side of a respective one supporting block 1011, and a second end of the one inner bar 1013 (opposing to the first end thereof) is connected to a side of another respective supporting block 1011, while a first end of one outer bar 1012 is connected to a side of a respective one supporting block 1014, and a second end of the one outer bar 1012 (opposing to the first end thereof) is connected to a side of another respective supporting block 1014, where the inner bars 1013 and the outer bars 1012 are spatially separated from each other. In other words, the inner bars 1013 and the outer bars 1012 of the heat dissipating element 1010A are not in physical contact with each other. In some embodiments, the supporting blocks 1011 are connected to and thermally coupled to the supporting blocks 1014 through a thermal interface material 850, respectively, so to form the heat dissipating element 1010B. The thermal interface material 850 may include any suitable thermally conductive material such as a polymer having a good thermal conductivity, which may be between about 3 W/m·K to about 10 W/m·K or more. The disclosure does not specifically limit a thickness of the thermal interface material 850 as long as the thermal interface material 850 is thick enough to sufficiently dissipating heat from the supporting blocks 1014 to the supporting blocks 1011. In some embodiments, the inner bars 1013 and portions of the supporting blocks 1011 together form a frame structure F1, and the outer bars 1012 and portions of the supporting blocks 1014 together form a frame structure F3, where the frame structure F1 is surrounded by the frame structure F3. With such frame structure of the thermal dissipating element 1010B, a stress buffer to the semiconductor package SP4 is obtained. The manufacture of the semiconductor package SP4 is compatible to the current and/or advanced manufacturing processes.

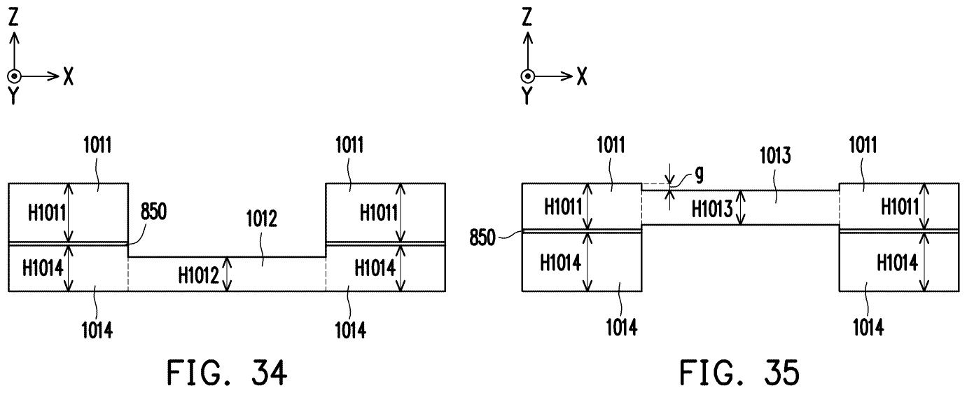

As shown in FIG. 33 through FIG. 35, for example, each inner bar 1013 has a width D4 (e.g., a shortest lateral size as measured in the direction X or Y) approximately ranging from 3 mm to 15 mm and a thickness H1013 (as measured in the direction Z) approximately ranging from 1.5 mm to 4.5 mm, each outer bar 1012 has a width D3 (e.g., a shortest lateral size as measured in the direction X or Y) greater than 3 mm and a thickness H1012 (as measured in the direction Z) approximately ranging from 0.5 mm to 1.0 mm, each supporting block 1011 has a first lateral size D1 (e.g., as measured in one of the direction X or Y) being greater than or substantially equal to a sum of the width D4 and the width D3, a second lateral size D2 (e.g., as measured in other one of the direction X or Y) being greater than or substantially equal to a sum of the width D4 and the width D3, and a thickness H1011 (as measured in the direction Z) approximately ranging from 3 mm to 5 mm, and each supporting block 1014 has the first lateral size D1 (e.g., as measured in one of the direction X or Y) being greater than or substantially equal to a sum of the width D4 and the width D3, the second lateral size D2 (e.g., as measured in other one of the direction X or Y) being greater than or substantially equal to a sum of the width D4 and the width D3, and a thickness H101 (as measured in the direction Z) approximately ranging from 3 mm to 5 mm. In some embodiments, a minimum distance g between an edge of one inner bar 1013 to an edge of the respective one supporting block 1011 is greater than or substantially equal to zero. For example, the minimum distance g is non-zero, also see the cross-sectional view of FIG. 35 taken along a line EE′ depicted in FIG. 33. In some embodiments, a minimum distance between an edge of one outer bar 1012 to an edge of the respective one supporting block 1014 is substantially equal to zero. For example, an illustrated bottom surface of the outer bar 1012 is substantially level with and substantially coplanar to illustrated bottom surfaces of the supporting blocks 1014 connected thereto, see the cross-sectional view of FIG. 34 taken along a line DD′ depicted in FIG. 33.

In some embodiments, the thickness H1011 of the supporting blocks 1011 is greater than the thickness H1013 of the inner bars 1013 (as shown in FIG. 33 and FIG. 35), and the thickness H1014 of the supporting blocks 1014 is greater than the thickness H1012 of the outer bars 1012 (as shown in FIG. 33 and FIG. 34). In some embodiments, all of the inner bars 1013 have the same width D4, with or without same thickness (e.g., H1013). Alternatively, some of the inner bars 1013 have different width D4, with or without same thickness (e.g., H1013). In some embodiments, all of the outer bars 1012 have the same width D3, with or without same thickness (e.g., H1012). Alternatively, some of the outer bars 1012 have different width D3, with or without same thickness (e.g., H1012). In some embodiments, all of the supporting blocks 1011 have the same lateral sizes D1 and D2, with or without same thickness (e.g., H1011). Alternatively, some of the supporting blocks 1011 have different lateral sizes D1 and/or different lateral sizes D2, with or without same thickness (e.g., H1011). In some embodiments, all of the supporting blocks 1014 have the same lateral sizes D1 and D2, with or without same thickness (e.g., H1014). Alternatively, some of the supporting blocks 1014 have different lateral sizes D1 and/or different lateral sizes D2, with or without same thickness (e.g., H1014).

In some embodiments, the size of the supporting blocks 1014 is substantially identical the size of the supporting blocks 1011, see FIG. 18 and FIG. 33. However, the disclosure is not limited thereto; alternatively, the size of the supporting blocks 1014 is different from the size of the supporting blocks 1011. For a non-limiting example, the size of the supporting blocks 1014 is greater than the size of the supporting blocks 1011, in the X-Y plane. In other words, in the X-Y plane, the projections of the supporting blocks 1011 are completely within the projections of the supporting blocks 1014, respectively. For another non-limiting example, the size of the supporting blocks 1014 is less than the size of the supporting blocks 1011, in the X-Y plane. In other words, in the X-Y plane, the projections of the supporting blocks 1014 are completely within the projections of the supporting blocks 1011, respectively.

Back to FIG. 18 and FIG. 19, in some embodiments, the inner bars 1013 (e.g., 1013a, 1013b, 1013c, 1013d) of the heat dissipating element 1010B are disposed on and thermally coupled to the semiconductor devices 400 (e.g., 400a, 400b, 400c, 400d) through the thermal interface material 830, respectively. On the other hand, the outer bars 1012 (e.g., 1012a, 1012b, 1012c, 1012d) and the supporting blocks 1014 (e.g., 1014a, 1014b, 1014c, 1014d) of the heat dissipating element 1010B are disposed on the substrate 500 through a bonding element 820, for example, as shown in FIG. 18 through FIG. 22.

The heat dissipating element 1010B may be formed by, but not limited to, forging and stamping, CNC processes, punching press, shaping, milling or the like. The heat dissipating element 1010B, for example, has a high thermal conductivity between about 200 W/m·K to about 400 W/m·K or more, and is formed using a metal, a metal alloy, and the like. However, the disclosure is not limited thereto. In some embodiments, the supporting blocks 1011 and the inner bars 1013 of the heat dissipating element 1010B are formed as an integral piece, and the supporting blocks 1014 and the outer bars 1012 of the heat dissipating element 1010B are formed as an integral piece. The heat dissipating element 1010B has a two-piece structure. In some embodiments, in the heat dissipating module 1000C, the heat dissipating element 1020A is overlapped with the heat dissipating element 1010B. The heat dissipating element 1020A includes a first portion 1021 and a second portion 1022A surrounding the first portion 1021, and the second portion 1022A of the heat dissipating element 1020A is overlapped with the heat dissipating element 1010B and connected to the heat dissipating element 1010B (e.g., through the thermal interface material 840), for example. In some embodiments, the semiconductor package SP4 is a CoWoS package equipped with optics for optical signal transmission.

Alternatively, the thermal interface material 840 may be omitted, see the semiconductor package SP5 shown in FIG. 23 through FIG. 27. For example, the second portion 1022A of the heat dissipating element 1020A is overlapped with the heat dissipating element 1010B, and there is an air gap between the second portion 1022A of the heat dissipating element 1020A and the heat dissipating element 1010B.

The disclosure is not limited thereto. In an alternative embodiment, the heat dissipating element 1020A is substituted by an heat dissipating element 1020B, where the heat dissipating element 1020B is not overlapped with the heat dissipating element 1010B, see a heat dissipating module 1000D of the semiconductor package SP6 shown in FIG. 28 through FIG. 32. The heat dissipating module 1000D includes a heat dissipating element 1010B and the dissipating element 1020B, where the heat dissipating element 1020B includes a first portion 1021 and a second portion 1022B surrounding the first portion 1021, and the second portion 1022B of the heat dissipating element 1020B is not overlapped with the heat dissipating element 1010B, for example.

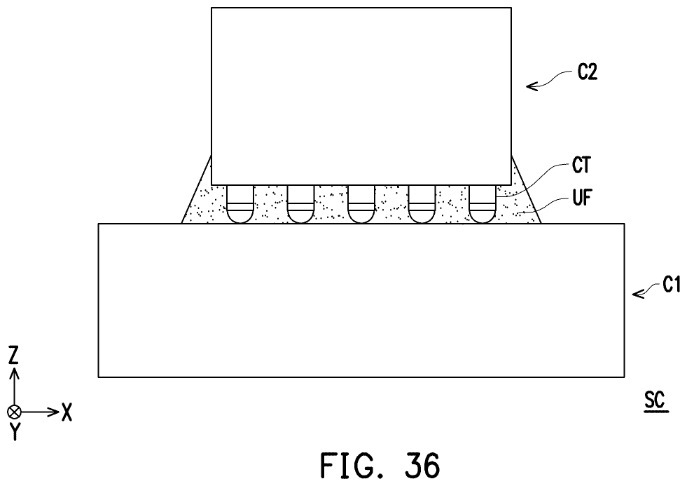

The semiconductor packages SP1, SP2, SP3, SP4 or the modifications thereof may be further mounted onto another external/additional electronical component, for example, mounted onto a circuit structure, such as a motherboard, a package substrate, another printed circuit board (PCB), a printed wiring board, and/or other carrier that is capable of carrying integrated circuits. FIG. 36 is a schematic cross-sectional view of an application of a semiconductor package in accordance with some embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 36, in some embodiments, a component assembly SC including a first component C1 and a second component C2 disposed over the first component C1 is provided. The first component C1 may be or may include a circuit structure, such as a motherboard, a package substrate, another PCB, a printed wiring board, an interposer, and/or other carrier that is capable of carrying integrated circuits. In some embodiments, the second component C2 mounted on the first component C1 is similar to one of the semiconductor packages SP1, SP2, SP3, SP4 or the modifications thereof. In a non-limiting example, one or more semiconductor package (e.g., one or multiple semiconductor packages SP1, SP2, SP3, SP4 and/or the modifications thereof) may be electrically coupled to the first component C1 through a plurality of terminals CT. The terminals CT may be the connectors 630 as previously described.

In some embodiments, an underfill UF is formed between the gap of the first component C1 and the second component C2 to at least laterally cover the terminals CT. Alternatively, the underfill UF is omitted. The underfill UF may be any acceptable material, such as a polymer, epoxy resin, molding underfill, or the like, for example. In one embodiment, the underfill may be formed by underfill dispensing, a capillary flow process, or any other suitable method. Owing to the underfill UF, a bonding strength between the first component C1 and the second component C2 is enhanced.

In accordance with some embodiments, a semiconductor package includes a substrate; a package, disposed over and electrically coupled to the substrate, and comprising a plurality of dies; a plurality of semiconductor devices, disposed over and electrically coupled to the substrate and laterally next to the package; and a thermal dissipating module, disposed over the substrate and comprising: a first thermal dissipating element, connected to and thermally coupled to the package through a first thermal interface material; and a second thermal dissipating element, connected to and thermally coupled to the plurality of semiconductor devices through a second thermal interface material, wherein a thermal conductivity of the first thermal interface material is different from a thermal conductivity of the second thermal interface material.

In accordance with some embodiments, a semiconductor package includes a substrate; a package, disposed over the substrate and comprising a plurality of dies; a plurality of semiconductor devices, disposed over the substrate and surrounding the package; and a first thermal dissipating element, disposed over the substrate and comprising: a plurality of supporting blocks; a plurality of inner bars, connected to the plurality of supporting blocks in a manner of a first frame structure, wherein the plurality of inner bars are connected to the plurality of semiconductor devices; and a plurality of outer bars, connected to the plurality of supporting blocks in a manner of a second frame structure, wherein the plurality of outer bars and the plurality of supporting blocks are connected to the substrate, wherein the first frame structure is surrounded by the second frame structure.

In accordance with some embodiments, a method of manufacturing a semiconductor package includes the following steps: providing a substrate; mounting a package comprising a plurality of dies to the substrate; mounting a plurality of semiconductor devices to the substrate, the plurality of semiconductor devices and the package are disposed at a side of the substrate; and disposing a thermal dissipating module over the substrate, the thermal dissipating module comprising a first thermal dissipating element connected to and thermally coupled to the package through a first thermal interface material and a second thermal dissipating element connected to and thermally coupled to the plurality of semiconductor devices through a second thermal interface material, wherein a thermal conductivity of the first thermal interface material is different from a thermal conductivity of the second thermal interface material.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor package, comprising:
a substrate;
a package, disposed over and electrically coupled to the substrate, and comprising a plurality of dies;
a plurality of semiconductor devices, disposed over and electrically coupled to the substrate and laterally next to the package; and
a thermal dissipating module, disposed over the substrate and comprising:
a first thermal dissipating element, connected to and thermally coupled to the package through a first thermal interface material; and
a second thermal dissipating element, connected to and thermally coupled to the plurality of semiconductor devices through a second thermal interface material,
wherein a thermal conductivity of the first thermal interface material is different from a thermal conductivity of the second thermal interface material.

2. The semiconductor package of claim 1, wherein the thermal conductivity of the first thermal interface material is greater than the thermal conductivity of the second thermal interface material.

3. The semiconductor package of claim 1, wherein the package is a CoW package.

4. The semiconductor package of claim 1, wherein the plurality of semiconductor devices comprises optical dies with an integration of an electrical-integrated-circuit and a photonic-integrated-circuit.

5. The semiconductor package of claim 1, wherein along a stacking direction of the substrate and the package, a projection of the first thermal dissipating element is overlapped with a projection of the second thermal dissipating element.

6. The semiconductor package of claim 1, wherein along a stacking direction of the substrate and the package, a projection of the first thermal dissipating element is offset from a projection of the second thermal dissipating element.

7. The semiconductor package of claim 1, wherein in a cross-section of the semiconductor package, the first thermal dissipating element is connected to the second thermal dissipating element through a third thermal interface material.

8. The semiconductor package of claim 1, wherein in a cross-section of the semiconductor package, there is an air gap is vertically between the first thermal dissipating element and the second thermal dissipating element.

9. A semiconductor package, comprising:
a substrate;
a package, disposed over the substrate and comprising a plurality of dies;
a plurality of semiconductor devices, disposed over the substrate and surrounding the package; and
a first thermal dissipating element, disposed over the substrate and comprising:
a plurality of supporting blocks;
a plurality of inner bars, connected to the plurality of supporting blocks in a manner of a first frame structure, wherein the plurality of inner bars are connected to the plurality of semiconductor devices; and
a plurality of outer bars, connected to the plurality of supporting blocks in a manner of a second frame structure, wherein the plurality of outer bars and the plurality of supporting blocks are connected to the substrate,
wherein the first frame structure is surrounded by the second frame structure.

10. The semiconductor package of claim 9, wherein the plurality of inner bars are spatially separated from the plurality of outer bars.

11. The semiconductor package of claim 9, wherein the plurality of supporting blocks, the plurality of inner bars and the plurality of outer bars are an integral piece.

12. The semiconductor package of claim 9, wherein each of the plurality of supporting blocks comprises a first supporting block and a second supporting block connecting to the first supporting block with a thermal interface material,
wherein:
the plurality of inner bars are connected to the first supporting blocks of the plurality of supporting blocks, and the plurality of inner bars and the first supporting blocks of the plurality of supporting blocks are a first integral piece
the plurality of outer bars are connected to the second supporting blocks of the plurality of supporting blocks, and the plurality of outer bars and the second supporting blocks of the plurality of supporting blocks are a second integral piece.

13. The semiconductor package of claim 9, further comprising:
a second thermal dissipating element, disposed over the package;
a first thermal interface material, disposed between and thermally coupling the first thermal dissipating element and the plurality of semiconductor device; and
a second thermal interface material, disposed between and thermally coupling the second thermal dissipating element and the package.

14. The semiconductor package of claim 13, wherein a thermal conductivity of the second thermal interface material is greater than or substantially equal to a thermal conductivity of the first thermal interface material.

15. The semiconductor package of claim 13, wherein in a cross-section of the semiconductor package, the first thermal dissipating element is connected to the second thermal dissipating element through a third thermal interface material.

16. The semiconductor package of claim 13, wherein in a cross-section of the semiconductor package, there is an air gap is vertically between the first thermal dissipating element and the second thermal dissipating element.

17. A method of manufacturing a semiconductor package, comprising:
providing a substrate;
mounting a package comprising a plurality of dies to the substrate;
mounting a plurality of semiconductor devices to the substrate, the plurality of semiconductor devices and the package are disposed at a side of the substrate; and
disposing a thermal dissipating module over the substrate, the thermal dissipating module comprising a first thermal dissipating element connected to and thermally coupled to the package through a first thermal interface material and a second thermal dissipating element connected to and thermally coupled to the plurality of semiconductor devices through a second thermal interface material, wherein a thermal conductivity of the first thermal interface material is different from a thermal conductivity of the second thermal interface material.

18. The method of claim 17, wherein the second thermal dissipating is formed in a one-piece structure comprising:
a plurality of supporting blocks;
a plurality of inner bars, connected to the plurality of supporting blocks in a manner of a first frame structure, wherein the plurality of inner bars are connected to the plurality of semiconductor devices; and
a plurality of outer bars, connected to the plurality of supporting blocks in a manner of a second frame structure, wherein the plurality of outer bars and the plurality of supporting blocks are connected to the substrate,
wherein the first frame structure is surrounded by the second frame structure.

19. The method of claim 17, wherein the second thermal dissipating is formed in a two-piece structure comprising:
a first piece, comprising:
a plurality of first supporting blocks;
a plurality of inner bars, connected to the plurality of first supporting blocks in a manner of a first frame structure, wherein the plurality of inner bars are connected to the plurality of semiconductor devices;
a second piece, comprising:
a plurality of second supporting blocks;
a plurality of outer bars, connected to the plurality of second supporting blocks in a manner of a second frame structure, wherein the plurality of outer bars and the plurality of supporting blocks are connected to the substrate, wherein the first frame structure is surrounded by the second frame structure; and
a third thermal interface material, connecting the first frame structure and the second frame structure.

20. The method of claim 17, further comprising:
mounting the substrate to a motherboard.
